(19) United States
(12) Patent Application Publication
(10) Pub. No.: US 2026/0271454 A1
(43) Pub. Date: Sep. 10, 2026

(54) DISPLAY DEVICE, METHOD OF MANUFACTURING THE DISPLAY DEVICE, AND ELECTRONIC DEVICE INCLUDING THE SAME

(71) Applicant: Samsung Display Co., Ltd., Yongin-si (KR)

(72) Inventors: SUNKWANG KIM, Yongin-si (KR); SI HYUN AHN, Yongin-si (KR); KYEUK LEE, Yongin-si (KR); SEONGYOUNG LEE, Yongin-si (KR)

(21) Appl. No.: 19/348,330

(22) Filed: Oct. 2, 2025

(30) Foreign Application Priority Data
Mar. 7, 2025 (KR) 10-2025-0029620

(51) Int. Cl. H10H 29/49; H10H 29/01; H10H 29/37; H10H 29/80; H10H 29/85; H10H 29/853

(52) U.S. Cl. CPC H10H 29/49; H10H 29/012; H10H 29/032; H10H 29/0362; H10H 29/37; H10H 29/8325; H10H 29/8517; H10H 29/853

(57) ABSTRACT

A display device includes: a base substrate including a display area including emission areas and a non-emission area around the emission areas and a pad area outside the display area; a conductive pattern in the pad area; a passivation layer on the conductive pattern; light-emitting elements on the passivation layer; an encapsulation layer on the light-emitting elements; a bank in the non-emission area on the encapsulation layer and defining openings corresponding to the emission areas; a reflective conductive layer including a mesh portion at least partially covering the bank and a connection portion extending from the mesh portion to the pad area; color conversion patterns respectively in the openings of the bank; a capping layer on the bank, the reflective conductive layer, and the color conversion patterns; and a connection pattern on the capping layer and electrically connecting the connection portion of the reflective conductive layer and the conductive pattern.

### CROSS-REFERENCE TO RELATED APPLICATION

The present application claims priority to and the benefit of Korean Patent Application No. 10-2025-0029620, filed on Mar. 7, 2025, in the Korean Intellectual Property Office, the entire disclosure of which is incorporated herein by reference.

### BACKGROUND

### 1. Field

One or more embodiments of the present disclosure relate to a display device, a method of manufacturing the display device, and an electronic device including the same. For example, one or more embodiments of the present disclosure relate to a display device that provides visual information, a method of manufacturing the display device, and an electronic device including the same.

### 2. Description of the Related Art

With the advancement of information technology, display devices have become increasingly important as interfaces between users and digital content. Accordingly, the use of display devices, such as liquid crystal display devices and/or organic light emitting display devices, has become widespread.

To enhance (improve) display quality, display devices including a color filter layer and a color conversion pattern have been researched. The color conversion pattern is capable of converting the wavelength of light provided to the display device. Accordingly, the display device including the color conversion pattern may be to emit light having a color different from the color of an incident light. For example, the color conversion pattern may include wavelength conversion particles, such as quantum dots.

### SUMMARY

One or more aspects of embodiments of the present disclosure are directed toward a display device with improved reliability.

One or more aspects of embodiments of the present disclosure are directed toward a method of manufacturing the display device.

One or more aspects of embodiments of the present disclosure are directed toward an electronic device including the display device.

Additional aspects will be set forth in part in the description which follows and, in part, will be apparent from the description, or may be learned by practice of the presented embodiments.

According to one or more embodiments of the present disclosure, a display device includes a first base substrate including a display area including emission areas and a non-emission area around (e.g., surrounding) the emission areas and a pad area outside the display area, transistors arranged in the display area on the first base substrate, a conductive pattern arranged in the pad area on the first base substrate, a passivation layer on (e.g., arranged on) the transistors and the conductive pattern, light-emitting elements respectively arranged in the emission areas on the passivation layer and respectively electrically connected to the transistors, an encapsulation layer on (e.g., arranged on) the light-emitting elements, a first bank arranged in the non-emission area on the encapsulation layer and defining openings respectively corresponding to the emission areas, a reflective conductive layer including a mesh portion at least partially covering the first bank in the display area and a connection portion extending from the mesh portion to the pad area, color conversion patterns respectively arranged in the openings of the first bank, a first capping layer on (e.g., arranged on) the first bank, the reflective conductive layer, and the color conversion patterns, and a connection pattern on (e.g., arranged on) the first capping layer and electrically connecting the connection portion of the reflective conductive layer and the conductive pattern.

In one or more embodiments, the connection pattern may include a first portion overlapping the connection portion of the reflective conductive layer in the pad area, in a plan view, and a second portion overlapping the conductive pattern in the pad area, in a plan view.

In one or more embodiments, the first portion of the connection pattern may be connected to the connection portion of the reflective conductive layer through a first contact hole penetrating the first capping layer. The second portion of the connection pattern may be connected to the conductive pattern through a second contact hole penetrating the first capping layer and the passivation layer.

In one or more embodiments, the display device may further include a second capping layer on (e.g., arranged on) the first capping layer and the connection pattern.

In one or more embodiments, the second capping layer may cover the entire first portion of the connection pattern.

In one or more embodiments, a connection pattern opening may be defined in the second capping layer to expose an upper surface of the second portion of the connection pattern.

In one or more embodiments, the second capping layer may cover the entire second portion of the connection pattern.

In one or more embodiments, the display device may further include pads in (e.g., arranged in) the pad area and spaced and/or apart (e.g., spaced apart or separated) from each other in a (e.g., one) direction.

In one or more embodiments, each of the pads may include a first pad electrode under (e.g., arranged under) the passivation layer, and a second pad electrode on (e.g., arranged on) the first capping layer and electrically connected to the first pad electrode.

In one or more embodiments, the second pad electrode may be connected to the first pad electrode through a pad contact hole penetrating the first capping layer and the passivation layer.

In one or more embodiments, the second pad electrode and the connection pattern may be in a same layer.

In one or more embodiments, a pad opening may be defined in the second capping layer to expose an upper surface of the second pad electrode.

In one or more embodiments, a constant voltage may be applied to the conductive pattern.

In one or more embodiments, the display device may further include a second base substrate opposite to (e.g., facing) the first base substrate, a color filter layer under (e.g., arranged under) the second base substrate, and a filling layer between (e.g., arranged between) the color filter layer and the first capping layer.

In one or more embodiments, the connection portion of the reflective conductive layer may extend beyond the second base substrate, in a plan view.

In one or more embodiments, the display device may further include a second bank on (e.g., arranged on) the first bank and including a liquid-repellent material.

In one or more embodiments, the mesh portion of the reflective conductive layer may cover the entire first bank. The second bank may be directly on (e.g., arranged on) the mesh portion of the reflective conductive layer.

In one or more embodiments, the mesh portion of the reflective conductive layer may cover a peripheral portion of the first bank and expose a central portion of the first bank. The second bank may be directly on (e.g., arranged on) the central portion of the first bank and spaced and/or apart (e.g., spaced apart or separated) from the mesh portion of the reflective conductive layer.

According to one or more embodiments of the present disclosure, a method of manufacturing a display device includes forming transistors in a display area on a first base substrate including the display area including emission areas and non-emission area around (e.g., surrounding) the emission areas and a pad area arranged outside the display area, and forming a conductive pattern in the pad area, forming a passivation layer on the transistors and the conductive pattern, forming light-emitting elements respectively electrically connected to the transistors in the emission areas on the passivation layer, forming an encapsulation layer on the light-emitting elements, forming a first bank defining openings respectively corresponding to the emission areas in the non-emission area on the encapsulation layer, forming a reflective conductive layer including a mesh portion at least partially covering the first bank in the display area and a connection portion extending from the mesh portion to the pad area, forming color conversion patterns respectively in the openings of the first bank, forming a first capping layer on the first bank, the reflective conductive layer, and the color conversion patterns, and forming a connection pattern electrically connecting the connection portion of the reflective conductive layer and the conductive pattern on the first capping layer.

According to one or more embodiments of the present disclosure, an electronic device includes a display device and a processor which is configured to control the display device. The display device includes a first base substrate including a display area including emission areas and a non-emission area around (e.g., surrounding) the emission areas and a pad area outside the display area, transistors arranged in the display area on the first base substrate, a conductive pattern arranged in the pad area on the first base substrate, a passivation layer on (e.g., arranged on) the transistors and the conductive pattern, light-emitting elements respectively arranged in the emission areas on the passivation layer and respectively electrically connected to the transistors, an encapsulation layer on (e.g., arranged on) the light-emitting elements, a first bank arranged in the non-emission area on the encapsulation layer and defining openings respectively corresponding to the emission areas, a reflective conductive layer including a mesh portion at least partially covering the first bank in the display area and a connection portion extending from the mesh portion to the pad area, color conversion patterns respectively arranged in the openings of the first bank, a first capping layer on (e.g., arranged on) the first bank, the reflective conductive layer, and the color conversion patterns, and a connection pattern on (e.g., arranged on) the first capping layer and electrically connecting the connection portion of the reflective conductive layer and the conductive pattern.

In the display device according to one or more embodiments of the present disclosure, the first bank and the color conversion patterns, which were conventionally formed on a second base substrate, may be formed on the first base substrate. Accordingly, light loss of the display device may be reduced. In addition, the reflective conductive layer is formed on the first bank, allowing the light which would be blocked by the first bank to be reflected toward the color conversion patterns. Accordingly, the light efficiency of the display device may be improved by achieving higher luminance in case that a same voltage is applied. In other word, the display device of one or more embodiments of the present disclosure may consume a low power to achieve a same luminance compared to a display device in the art.

In addition, the display device according to one or more embodiments of the present disclosure may further include the connection pattern. The connection pattern may electrically connect the reflective conductive layer and the conductive pattern. Accordingly, it may prevent or reduce electrostatic discharge defects or signal coupling problems caused by the reflective conductive layer being left floating without being connected to another constant-voltage line. As a result, the reliability of the display device may be improved. For example, by forming the first bank and color conversion patterns on the first base substrate—rather than on a separate substrate—the device architecture is simplified, reducing alignment complexity and potential light loss. The reflective conductive layer, positioned over the first bank, not only enhances light directionality toward the color conversion patterns but also contributes to improved luminance efficiency. The connection portion of the reflective conductive layer, extending to the pad area, enables stable electrical grounding or biasing via the connection pattern, which links it to the conductive pattern. This configuration mitigates floating node issues and electrostatic discharge risks, thereby improving overall device reliability. The layered structure, including the passivation layer, encapsulation layer, and capping layers, further supports environmental protection and mechanical stability, making the device suitable for integration into high-performance electronic devices.

It is to be understood that both the foregoing general description and the following detailed description are illustrative and explanatory and are intended to provide further explanation of the disclosure to those skilled in the art.

### BRIEF DESCRIPTION OF THE DRAWINGS

The accompanying drawings, which are included to provide a further understanding of the disclosure and are incorporated in and constitute a part of this disclosure, illustrate embodiments of the disclosure, and together with the description serve to explain the disclosure. However, the illustrative embodiments may be embodied in different forms and should not be construed as limited to example embodiments set forth herein. Rather, these embodiments are provided so that this disclosure will be thorough and complete, and will fully convey the scope of the example embodiments to those skilled in the art. The above and other aspects, features, and advantages of certain embodiments of the present disclosure will be more apparent from the following description taken in conjunction with the accompanying drawings.

FIG. 1 is a schematic perspective view of a display device according to one or more embodiments of the present disclosure.

FIG. 2 is an enlarged plan view of the area A of FIG. 1 according to one or more embodiments of the present disclosure.

FIG. 3 is a cross-sectional view of an embodiment taken along the line I-I′ of FIG. 2.

FIG. 4 is a plan view of a lower substrate of the display device of FIG. 1 according to one or more embodiments of the present disclosure.

FIG. 5 is an enlarged plan view of an embodiment of the area B of FIG. 4.

FIG. 6 is a cross-sectional view taken along the line II-II′ of FIG. 5 according to one or more embodiments of the present disclosure.

FIG. 7 is a cross-sectional view taken along the line III-III′ of FIG. 5 according to one or more embodiments of the present disclosure.

FIG. 8 is an enlarged plan view of another embodiment of the area B of FIG. 4.

FIG. 9 is a cross-sectional view taken along the line IV-IV′ of FIG. 8 according to one or more embodiments of the present disclosure.

FIG. 10 is a cross-sectional view of another embodiment taken along the line I-I′ of FIG. 2.

FIGS. 11-20 are views of a method of manufacturing a display device according to one or more embodiments of the present disclosure.

FIG. 21 is a block diagram of an electronic device according to one or more embodiments of the present disclosure.

FIG. 22 illustrates schematic diagrams of electronic devices according to various embodiments of the present disclosure.

### DETAILED DESCRIPTION

Various example embodiments will be described more fully hereinafter with reference to the accompanying drawings, in which one or more example embodiments are shown. The present disclosure may, however, be embodied in many different forms and should not be construed as limited to the example embodiments set forth herein. Rather, these example embodiments are provided so that this disclosure will be thorough and complete, and will fully convey the scope of the present disclosure to those skilled in the art. In the drawings, the sizes and relative sizes of layers and regions may be exaggerated or reduced for clarity.

In this disclosure, a plane may be defined by a first direction D1 and a second direction D2 which intersects the first direction D1. For example, the second direction D2 may be normal (e.g., perpendicular) to the first direction D1. In addition, a third direction D3 may be a normal direction of the plane. For example, the third direction D3 may be perpendicular to the plane defined by the first direction D1 and the second direction D2. In addition, the term “plan view” or “in a plan view” may refer to a state, in which it is viewed from a direction (e.g., a thickness direction) normal to the plane defined by the first direction D1 and the second direction D2. And the term “cross-sectional view” or “in a cross-sectional view” may refer to a state, in which it is viewed from the first direction D1 or the second direction D2.

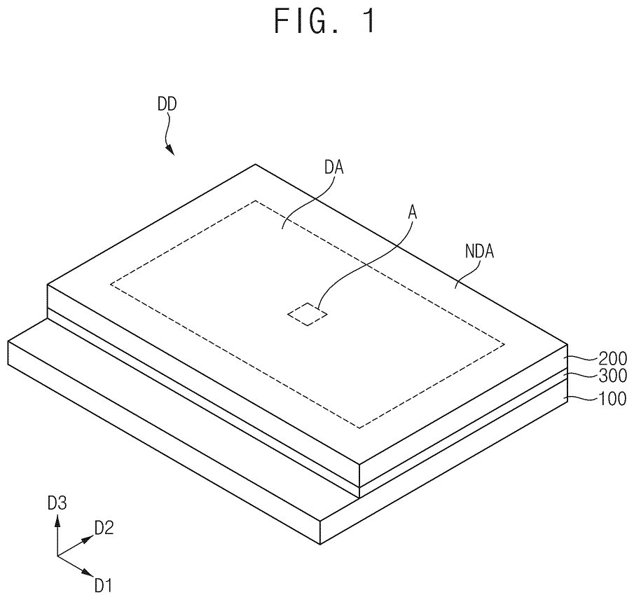

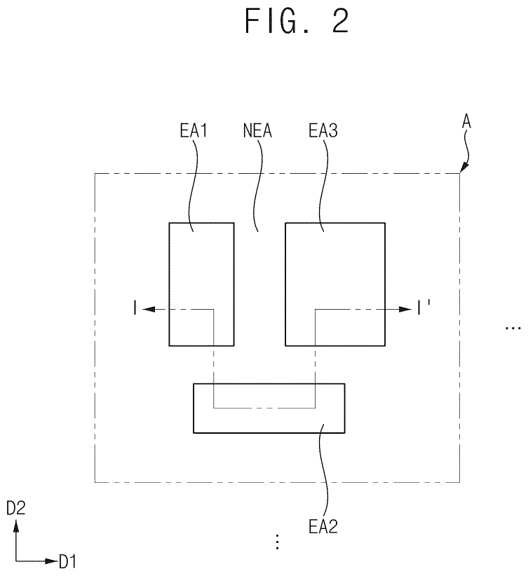

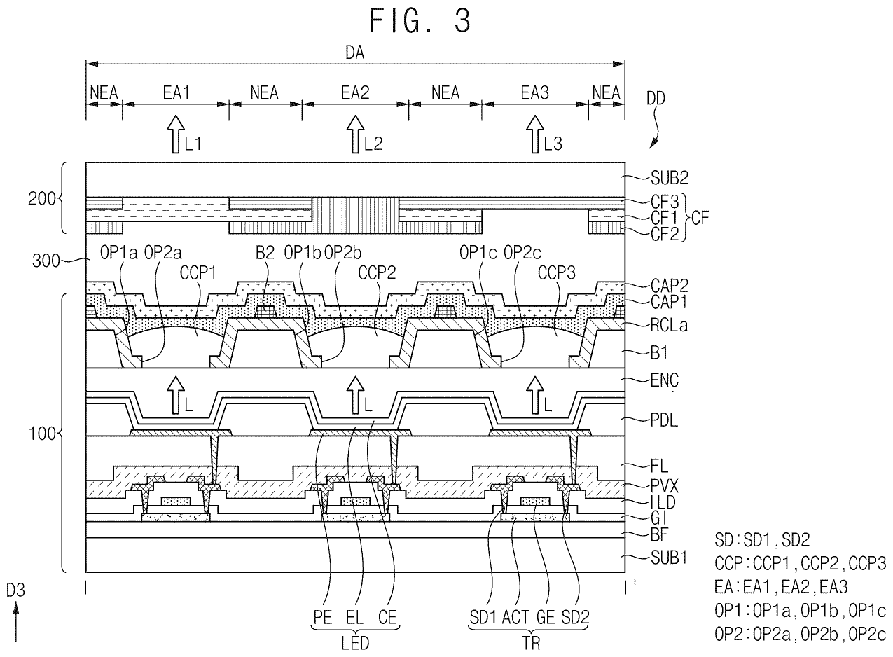

FIG. 1 is a schematic perspective view of a display device according to one or more embodiments of the present disclosure. FIG. 2 is an enlarged plan view of the area A of FIG. 1 according to one or more embodiments. FIG. 3 is a cross-sectional view of an embodiment taken along the line I-I′ of FIG. 2.

Referring to FIG. 1, a display device DD according to one or more embodiments may include a lower substrate 100, an upper substrate 200, and a filling layer 300.

The display device DD may be a device activated according to electrical signals. For example, the display device DD may be a mobile phone, a tablet, or a wearable device, but embodiments of the present disclosure are not limited thereto.

The display device DD may include a display area DA and a non-display area NDA. The display area DA may be an area which displays an image by generating light or by controlling the transmittance of light provided from an external light source. The non-display area NDA may be located around the display area DA. For example, in a plan view, the non-display area NDA may surround at least a portion of the display area DA. In one or more embodiments, the non-display area NDA may be an area which does not display an image. However, embodiments of the present disclosure are not limited thereto, and an image may be displayed in at least a portion of the non-display area NDA.

The filling layer 300 may be arranged between the lower substrate 100 and the upper substrate 200. The filling layer 300 may serve as a buffer against external pressure and/or the like applied to the display device DD. For example, in one or more embodiments, the filling layer 300 may maintain a gap between the lower substrate 100 and the upper substrate 200. The filling layer 300 may include a material capable of transmitting light. For example, the filling layer 300 may include polyimide, acrylate, and/or the like.

In one or more embodiments, the upper substrate 200 may have a shorter length in the second direction D2 than the lower substrate 100. However, embodiments of the present disclosure are not limited thereto, for example, in one or more embodiments, the upper substrate 200 may have a same length as the lower substrate 100 in the second direction D2. A detailed description of the lower substrate 100 and the upper substrate 200 will be provided later with reference to FIG. 3.

Referring to FIG. 2 and FIG. 3, the display area DA may include emission areas EA and a non-emission area NEA.

The emission areas EA may include a first emission area EA1, a second emission area EA2, and a third emission area EA3. Each of the first emission area EA1, the second emission area EA2, and the third emission area EA3 may be an area where light emitted from a light-emitting element LED is emitted to the outside of the display device DD. For example, the first emission area EA1 may be to emit first transmitted light L1, the second emission area EA2 may be to emit second transmitted light L2, and the third emission area EA3 may be to emit third transmitted light L3. In one or more embodiments, the first transmitted light L1 may be red light, the second transmitted light L2 may be green light, and the third transmitted light L3 may be blue light. However, embodiments of the present invention are not limited thereto. For example, in one or more embodiments, the emission areas EA may be combined to emit yellow light, cyan light, or magenta light. In one or more embodiments, the emission areas EA may be to emit four or more colors of light. For example, in one or more embodiments, the emission areas EA may be combined to emit at least one of yellow light, cyan light, or magenta light in addition to red light, green light, and blue light. In one or more embodiments, the emission areas EA may be combined to further emit white light.

In a plan view, each of the first emission area EA1, the second emission area EA2, and the third emission area EA3 may be repeatedly arranged along the first direction D1 and the second direction D2. In one or more embodiments, in a plan view, the first emission area EA1 and the third emission area EA3 may be repeatedly arranged in a first row of the display area DA, and the second emission area EA2 may be repeatedly arranged in a second row of the display area DA. However, embodiments of the present disclosure are not limited thereto.

The first emission area EA1, the second emission area EA2, and the third emission area EA3 may have different sizes. In one or more embodiments, a size of the third emission area EA3 may be larger than a size of the first emission area EA1 and a size of the second emission area EA2. However, this is merely an example, and the sizes of the first to third emission areas EA1, EA2, and EA3 may be variously determined as needed.

Each of the first emission area EA1, the second emission area EA2, and the third emission area EA3 may have a planar shape, such as a triangular shape, a rectangular shape, a circular shape, a track shape, an elliptical shape, and/or the like. In one or more embodiments, each of the first emission area EA1, the second emission area EA2, and the third emission area EA3 may have a rectangular planar shape.

The non-emission area NEA may surround the first to third emission areas EA1, EA2, and EA3, in a plan view. For example, the non-emission area NEA may have a grid shape, in a plan view. The non-emission area NEA may not emit light.

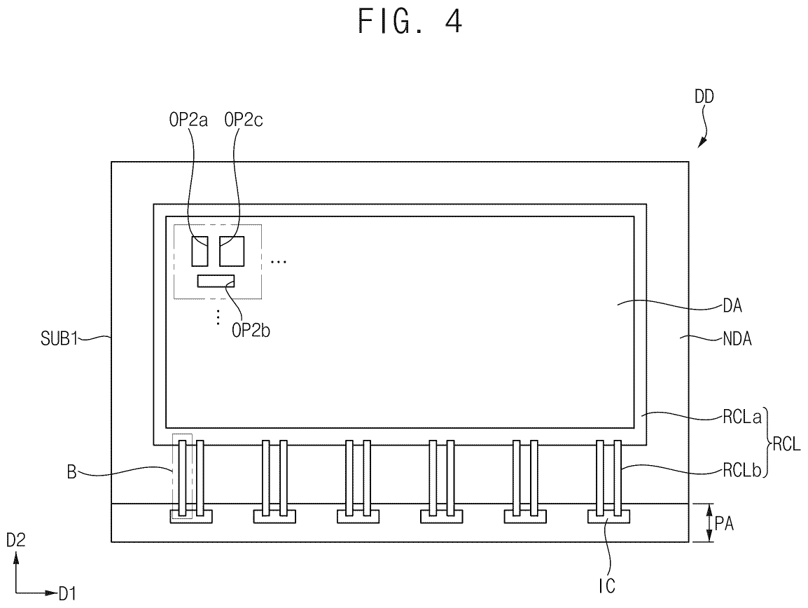

In one or more embodiments, the lower substrate 100 may include a first base substrate SUB1, a buffer layer BF, a gate insulating layer GI, an interlayer insulating layer ILD, a transistor TR, a passivation layer PVX, a planarization layer FL, a light-emitting element LED, a pixel defining layer PDL, an encapsulation layer ENC, a first bank B1, a reflective conductive layer RCL (see FIG. 3 and FIG. 4), color conversion patterns CCP, a second bank B2, a first capping layer CAP1, and a second capping layer CAP2. The transistor TR may include a first connection electrode SD1, a second connection electrode SD2, an active pattern ACT, and a gate electrode GE. The light-emitting element LED may include a pixel electrode PE, a light-emitting layer EL, and a common electrode CE.

The first base substrate SUB1 may include the display area DA including the emission areas EA and the non-emission area NEA around (e.g., surrounding) the emission areas EA and a pad area PA outside the display area DA (see FIG. 3 and FIG. 4). The first base substrate SUB1 may be an insulating substrate formed of a transparent material or an opaque material. In one or more embodiments, the first base substrate SUB1 may include glass. In these embodiments, the lower substrate 100 may be a rigid display substrate. In one or more embodiments, the first base substrate SUB1 may include plastic. In these embodiments, the lower substrate 100 may be a flexible display substrate.

In one or more embodiments, a lower metal layer, at least partially overlapping the active pattern ACT of the transistor TR, may be arranged on the first base substrate SUB1. The lower metal layer may serve to protect the active pattern ACT from external light. The lower metal layer may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu). In addition, the lower metal layer may be formed as a single-layer or a multi-layer of one or more selected from among the above materials.

The buffer layer BF may be arranged on the substrate SUB1. The buffer layer BF may prevent or reduce impurities, such as oxygen and/or moisture from diffusing to an upper surface of the first substrate SUB1 through the first substrate SUB1, and may planarize the upper surface of the first substrate SUB1. In one or more embodiments, the buffer layer BF may include an inorganic insulating material, such as a silicon compound, a metal oxide, and/or the like. For example, the buffer layer BF may include silicon oxide (SiOₓ), silicon nitride (SiNₓ), silicon oxynitride (SiOₓN_{y}), silicon oxycarbide (SiOₓC_{y}), silicon carbonitride (SiCₓN_{y}), aluminum oxide (AlOₓ), aluminum nitride (AlNₓ), tantalum oxide (TaOₓ), hafnium oxide (HfOₓ), zirconium oxide (ZrOₓ), titanium oxide (TiOₓ), and/or the like. These may be used alone or in combination with each other.

The active pattern ACT may be arranged in the display area DA on the buffer layer BF. For example, in one or more embodiments, the active pattern ACT may include a silicon semiconductor, such as amorphous silicon, polycrystalline silicon, and/or the like. In one or more embodiments, the active pattern ACT may include a metal oxide semiconductor. The active pattern ACT may have a source region, a drain region, and a channel region located between the source region and the drain region.

The gate insulating layer GI may be arranged on the buffer layer BF. For example, the gate insulating layer GI may cover the active pattern ACT, and may be formed along the profile of the active pattern ACT with a substantially uniform thickness. The gate insulating layer GI may insulate the channel region of the active pattern ACT and the gate electrode GE arranged on the gate insulating layer GI. For example, the gate insulating layer GI may include an inorganic insulating material.

The gate electrode GE may be arranged in the display area DA on the gate insulating layer GI. The gate electrode GE may overlap the channel region of the active pattern ACT. In one or more embodiments, the gate electrode GE may include a conductive material, such as a metal, a metal alloy, a conductive metal nitride, a conductive metal oxide, a transparent conductive material, and/or the like. For example, the gate electrode GE may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), an aluminum-containing alloy, a silver-containing alloy, a copper-containing alloy, a molybdenum-containing alloy, aluminum nitride (AlNₓ), tungsten nitride (WNₓ), titanium nitride (TiNₓ), chromium nitride (CrNₓ), tantalum nitride (TaNₓ), strontium ruthenium oxide (SrRuOₓ), zinc oxide (ZnOₓ), indium tin oxide (ITO), tin oxide (SnOₓ), indium oxide (InOₓ), gallium oxide (GaOₓ), indium zinc oxide (IZO), and/or the like. These may be used alone or in combination with each other.

The interlayer insulating layer ILD may be arranged on the gate insulating layer GI. The interlayer insulating layer ILD may cover the gate electrode GE, and may be formed along the profile of the gate electrode GE with a substantially uniform thickness. For example, the interlayer insulating layer ILD may include an inorganic insulating material.

The first connection electrode SD1 and the second connection electrode SD2 may be arranged in the display area DA on the interlayer insulating layer ILD. In one or more embodiments, the first connection electrode SD1 may be connected to the source region of the active pattern ACT through a contact hole penetrating the interlayer insulating layer ILD and the gate insulating layer GI, and the second connection electrode SD2 may be connected to the drain region of the active pattern ACT through a contact hole penetrating the interlayer insulating layer ILD and the gate insulating layer GI. However, embodiments of the present disclosure are not limited thereto. For example, in one or more embodiments, the first connection electrode SD1 may be connected to the drain region of the active pattern ACT through a contact hole penetrating the interlayer insulating layer ILD and the gate insulating layer GI, and the second connection electrode SD2 may be connected to the source region of the active pattern ACT through a contact hole penetrating the interlayer insulating layer ILD and the gate insulating layer GI.

Accordingly, the transistor TR including the active pattern ACT, the first connection electrode SD1, the second connection electrode SD2, and the gate electrode GE may be arranged in the display area DA.

The passivation layer PVX may be arranged on the interlayer insulating layer ILD. The passivation layer PVX may cover the first connection electrode SD1 and the second connection electrode SD2, and may be formed along the profiles of the first connection electrode SD1 and the second connection electrode SD2 with a substantially uniform thickness. For example, the passivation layer PVX may include an inorganic insulating material.

The planarization layer FL may be arranged on the passivation layer PVX. The planarization layer FL may planarize underlying step differences so that the light-emitting element LED described later may be formed. The planarization layer FL may include an organic material to planarize the underlying step differences. For example, the planarization layer FL may include an acryl-based resin, an epoxy resin, a phenol resin, a polyamide-based resin, a polyimide-based resin, an unsaturated polyester-based resin, a polyphenylene-based resin, a polyphenylene sulfide-based resin, a benzocyclobutene-based resin, and/or the like.

The pixel electrode PE may be arranged in the display area DA on the planarization layer FL. In one or more embodiments, the pixel electrode PE may be connected to the second connection electrode SD2 through a contact hole penetrating the planarization layer FL and the passivation layer PVX. Accordingly, the pixel electrode PE may be electrically connected to the transistor TR. For example, the pixel electrode PE may include a conductive material. In one or more embodiments, the pixel electrode PE may function as an anode.

The pixel defining layer PDL may be arranged on the planarization layer FL. The pixel defining layer PDL may cover an edge of the pixel electrode PE, and may define a pixel opening exposing a central portion of the pixel electrode PE. The emission areas EA may be defined by the pixel opening. The pixel defining layer PDL may include an inorganic material or an organic material. In one or more embodiments, the pixel defining layer PDL may include an organic material, such as an epoxy resin, a siloxane resin, and/or the like. These may be used alone or in combination with each other. In one or more embodiments, the pixel defining layer PDL may further include a light-blocking material having a black color.

The light-emitting layer EL may be arranged on the pixel electrode PE and the pixel defining layer PDL. A portion of the light-emitting layer EL may be arranged in the pixel opening of the pixel defining layer PDL. In one or more embodiments, the light-emitting layer EL may extend continuously across a plurality of pixels. In one or more embodiments, the light-emitting layer EL may be separated from the light-emitting layer EL of an adjacent pixel. In one or more embodiments, the light-emitting layer EL may include an organic light-emitting material. Accordingly, the light-emitting layer EL may generate incident light L which enters the color conversion patterns CCP. In one or more embodiments, the light-emitting layer EL may generate blue light. In one or more embodiments, one or more other functional layers, such as a hole injection layer, a hole transport layer, an electron transport layer, and an electron injection layer may be arranged above and/or below the light-emitting layer EL.

The common electrode CE may be arranged on the light-emitting layer EL. The common electrode CE may extend continuously on the display area DA across a plurality of pixels. For example, the common electrode CE may include a conductive material. In one or more embodiments, the common electrode CE may function as a cathode. A common voltage (low power supply voltage) may be applied to the common electrode CE.

Accordingly, the light-emitting element LED including the pixel electrode PE, the light-emitting layer EL, and the common electrode CE may be arranged in the display area DA.

The encapsulation layer ENC may be arranged on the common electrode CE. The encapsulation layer ENC may prevent or reduce impurities, moisture, and/or the like from penetrating into the light-emitting element LED from the outside. The encapsulation layer ENC may include at least one inorganic layer and at least one organic layer. For example, the inorganic layer may include silicon oxide (SiOₓ), silicon nitride (SiNₓ), silicon oxynitride (SiOₓN_{y}), and/or the like. These may be used alone or in combination with each other. The organic layer may include a polymer cured material, such as polyacrylate, and/or the like.

The first bank B1 may be arranged in the display area DA on the encapsulation layer ENC. The first bank B1 may be arranged in the non-emission area NEA on the encapsulation layer ENC, and may define openings OP1 respectively corresponding to the emission areas EA. In one or more embodiments, the first bank B1 may define first to third openings OP1a, OP1b, and OP1c. The first to third openings OP1a, OP1b, and OP1c may be located in regions corresponding to the first to third emission areas EA1, EA2, and EA3, respectively. In a plan view, the first to third openings OP1a, OP1b, and OP1c may be repeatedly arranged along the first direction D1 and the second direction D2.

In one or more embodiments, the first to third openings OP1a, OP1b, and OP1c may serve as spaces for receiving an ink composition or an organic composition in the process of forming a first color conversion pattern CCP1, a second color conversion pattern CCP2, and a third color conversion pattern CCP3. For example, the first color conversion pattern CCP1 may be arranged in the first opening OP1a, the second color conversion pattern CCP2 may be arranged in the second opening OP1b, and the third color conversion pattern CCP3 may be arranged in the third opening OP1c.

In one or more embodiments, the first opening OP1a, the second opening OP1b, and the third opening OP1c may have different widths. The sizes of the first to third openings OP1a, OP1b, and OP1c may be variously determined as needed.

The first bank B1 may include an organic material. In one or more embodiments, the first bank B1 may further include a light-blocking material. For example, in one or more embodiments, at least a portion of the first bank B1 may include a light-blocking material, such as a black pigment, a black dye, carbon black, and/or the like.

In one or more embodiments, the reflective conductive layer RCL (see FIG. 4) may be arranged in the display area DA on the first bank B1 and the encapsulation layer ENC. The reflective conductive layer RCL may include a mesh portion RCLa covering the entire first bank B1 and a connection portion RCLb (see FIG. 4) extending from the mesh portion RCLa to the pad area PA. The reflective conductive layer RCL may reflect even the incident light L which would be blocked by the first bank B1 toward the color conversion patterns CCP. Accordingly, the light efficiency of the display device may be improved by achieving higher luminance in case that a same voltage is applied. A detailed description of the reflective conductive layer RCL will be provided later with reference to FIG. 4.

The color conversion patterns CCP may be arranged on the encapsulation layer ENC. The color conversion patterns CCP may be surrounded by the first bank B1. For example, the color conversion patterns CCP may be surrounded by the mesh portion RCLa of the reflective conductive layer RCL which entirely covers the first bank B1. In one or more embodiments, the color conversion patterns CCP may convert the incident light L emitted from the light-emitting elements LED into light having a specific wavelength. For example, the color conversion patterns CCP may include color conversion particles.

The color conversion patterns CCP may include the first color conversion pattern CCP1, the second color conversion pattern CCP2, and the third color conversion pattern CCP3. The first to third conversion patterns CCP1, CCP2, and CCP3 may overlap the first to third emission areas EA1, EA2, and EA3, respectively. For example, the first to third color conversion patterns CCP1, CCP2, and CCP3 may be arranged in the first to third openings OP1a, OP1b, and OP1c defined by the first bank B1, respectively.

The first color conversion pattern CCP1 may convert the incident light L emitted from the light-emitting element LED into first transmitted light L1. In one or more embodiments, the incident light L may be blue light having an emission wavelength of about 380 nm to about 480 nm, and the first transmitted light L1 may be red light having an emission wavelength of about 600 nm to about 650 nm. For example, in one or more embodiments, the first color conversion pattern CCP1 may include a first photosensitive polymer, a first scattering material, and first color conversion particles.

The first scattering material may increase the optical path by scattering the incident light L without substantially changing the wavelength of the incident light L entering the first color conversion pattern CCP1. In one or more embodiments, the first scattering material may include a metal oxide. Non-limiting examples of the metal oxide which may be used as the first scattering material may include titanium oxide (TiOₓ), aluminum oxide (AlOₓ), zinc oxide (ZnOₓ), indium tin oxide (ITO), and/or the like. These may be used alone or in combination with each other. In one or more embodiments, the first scattering material may not be provided.

In one or more embodiments, the first color conversion pattern CCP1 may include quantum dots. The quantum dots may be defined as semiconductor materials having nanocrystals (e.g., sizes in nanometers). The quantum dots may have specific bandgaps depending on their composition and size. Accordingly, the quantum dots may be to absorb the incident light L, and may be to emit light having a wavelength different from the wavelength of the incident light L. For example, the quantum dots may have a diameter (e.g., average diameter) of about 100 nm or less, for example, a diameter (e.g., average diameter) in a range of about 1 nm to about 20 nm. For example, the first color conversion particles of the first color conversion pattern CCP1 may include quantum dots which absorb blue light and emit red light. In the present disclosure, when quantum dots or quantum dot particles are spherical, “diameter” indicates a particle diameter or an average particle diameter, and when the particles are non-spherical, the “diameter” indicates a major axis length or an average major axis length. The diameter of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter is referred to as D50. D50 refers to the average diameter of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

The first scattering material and the first color conversion particles may be dispersed in the first photosensitive polymer. For example, the first photosensitive polymer may include an epoxy-based resin, an acrylic-based resin, a phenol-based resin, a melamine-based resin, an imide-based resin, and/or the like.

The second color conversion pattern CCP2 may convert the incident light L emitted from the light-emitting element LED into second transmitted light L2. In one or more embodiments, the incident light L may be blue light having an emission wavelength of about 380 nm to about 480 nm, and the second transmitted light L2 may be green light having an emission wavelength of about 500 nm to about 550 nm. For example, the second color conversion pattern CCP2 may include a second photosensitive polymer, a second scattering material, and second color conversion particles.

In one or more embodiments, the second color conversion particles of the second color conversion pattern CCP2 may include quantum dots which absorb blue light and emit green light.

The third color conversion pattern CCP3 may convert the incident light L emitted from the light-emitting element LED into third transmitted light L3. In one or more embodiments, the third color conversion pattern CCP3 may be to transmit the incident light L emitted from the light-emitting element LED without converting the incident light L. In one or more embodiments, the incident light L may be blue light having an emission wavelength of about 380 nm to about 480 nm, and the third transmitted light L3 may be blue light having substantially the same wavelength as the wavelength of the incident light L.

According to one or more embodiments, as the color conversion patterns CCP are included on the lower substrate 100 and are directly arranged on the encapsulation layer ENC, a distance between the light-emitting element LED and the color conversion patterns CCP may be reduced. Accordingly, the density (e.g., intensity) of the incident light L entering the color conversion patterns CCP may increase, the conversion efficiency of the incident light L may increase, and the light efficiency of the display device DD may be improved.

The second bank B2 may be arranged on the first bank B1. The second bank B2 may be arranged on the mesh portion RCLa of the reflective conductive layer RCL. In one or more embodiments, the second bank B2 may include a liquid-repellent material or may be treated to have a hydrophobic surface. Accordingly, in a process that forming the color conversion patterns CCP in each of the emission areas EA by an inkjet printing process and/or the like, ink including a light-emitting material (e.g., color conversion particles/material) and/or the like may stably flow into each of the emission areas EA. In one or more embodiments, the mesh portion RCLa of the reflective conductive layer RCL may cover the entire first bank B1, and the second bank B2 may be directly arranged on the mesh portion RCLa of the reflective conductive layer RCL.

The first capping layer CAP1 may be arranged on the second bank B2, the mesh portion RCLa, and the color conversion patterns CCP. The first capping layer CAP1 may cover the color conversion patterns CCP. The first capping layer CAP1 may prevent or reduce the color conversion patterns CCP from being damaged or contaminated by impurities, such as moisture and/or air penetrating from the outside. For example, in one or more embodiments, the first capping layer CAP1 may include at least one inorganic material selected from among silicon oxide (SiOₓ), silicon nitride (SiNₓ), silicon oxynitride (SiOₓN_{y}), aluminum oxide (AlOₓ), and titanium oxide (TiOₓ), and may be formed as a single-layer or a multi-layer, but embodiments of the present disclosure are not limited thereto.

The second capping layer CAP2 may be arranged on the first capping layer CAP1. For example, the second capping layer CAP2 may be arranged between a color filter layer CF of the upper substrate 200 and the first capping layer CAP1. For example, in one or more embodiments, the second capping layer CAP2 may include at least one insulating material selected from among silicon oxide (SiOₓ), silicon nitride (SiNₓ), silicon oxynitride (SiOₓN_{y}), aluminum oxide (AlOₓ), and titanium oxide (TiOₓ), and may be formed as a single-layer or a multi-layer, but embodiments of the present disclosure are not limited thereto. A detailed description of the second capping layer CAP2 will be provided later.

The upper substrate 200 may be arranged in the third direction D3 from the lower substrate 100. The upper substrate 200 may include a second base substrate SUB2 and the color filter layer CF.

The second base substrate SUB2 may be an insulating substrate formed of a transparent material. The second substrate SUB2 may include glass, plastic, and/or the like. The second substrate SUB2 may include the emission areas EA and the non-emission area NEA.

The color filter layer CF may be arranged below the second base substrate SUB2. The color filter layer CF may include a first color filter CF1, a second color filter CF2, and a third color filter CF3. In one or more embodiments, the first color filter CF1, the second color filter CF2, and the third color filter CF3 may selectively transmit light of different wavelengths. For example, the first color filter CF1 may overlap the first emission area EA1, transmit red light, and block blue light and green light. The second color filter CF2 may overlap the second emission area EA2, transmit green light, and block blue light and red light. The third color filter CF3 may overlap the third emission area EA3, transmit blue light, and block red light and green light.

In one or more embodiments, each of the first to third color filters CF1, CF2, and CF3 may be arranged to further overlap the non-emission area NEA. As shown in FIG. 3 and FIG. 10, the first color filter CF1 may overlap the first emission area EA1 and the non-emission area NEA, and may not overlap the second emission area EA2 and the third emission area EA3. The second color filter CF2 may overlap the second emission area EA2 and the non-emission area NEA, and may not overlap the first emission area EA1 and the third emission area EA3. The third color filter CF3 may overlap the third emission area EA3 and the non-emission area NEA, and may not overlap the first emission area EA1 and the second emission area EA2. In this regard, portions of the first to third color filters CF1, CF2, and CF3 in the non-emission area NEA may overlap each other in the third direction D3. Accordingly, color mixing between adjacent the first to third emission areas EA1, EA2, and EA3 may be prevented or reduced.

FIG. 4 is a plan view of a lower substrate of the display device of FIG. 1 according to one or more embodiments of the present disclosure.

Referring to FIG. 4, the lower substrate 100 of the display device DD may include the display area DA and the non-display area NDA. The non-display area NDA may include the pad area PA outside the display area DA. An integrated circuit IC may be arranged in the pad area PA. In one or more embodiments, a plurality of integrated circuits IC may be arranged. However, embodiments of the present disclosure are not limited thereto, for example, in one or more embodiments, there may be one integrated circuit IC.

Referring to FIG. 3 and FIG. 4, the reflective conductive layer RCL may include the mesh portion RCLa and the connection portion RCLb. The mesh portion RCLa may be arranged in the non-emission area NEA on the encapsulation layer ENC, and may define reflection openings OP2 respectively corresponding to the emission areas EA. In one or more embodiments, the mesh portion RCLa of the reflective conductive layer RCL may define first to third reflection openings OP2a, OP2b, and OP2c. The first to third reflection openings OP2a, OP2b, and OP2c may be located in regions corresponding to the first to third emission areas EA1, EA2, and EA3, respectively. In a plan view, the first to third reflection openings OP2a, OP2b, and OP2c may be repeatedly arranged in the display area DA along the first direction D1 and the second direction D2.

In one or more embodiments, each of the first reflection opening OP2a, the second reflection opening OP2b, and the third reflection opening OP2c of the mesh portion RCLa may have different widths. The sizes of the first to third reflection openings OP2a, OP2b, and OP2c may be determined in one or more suitable ways as needed.

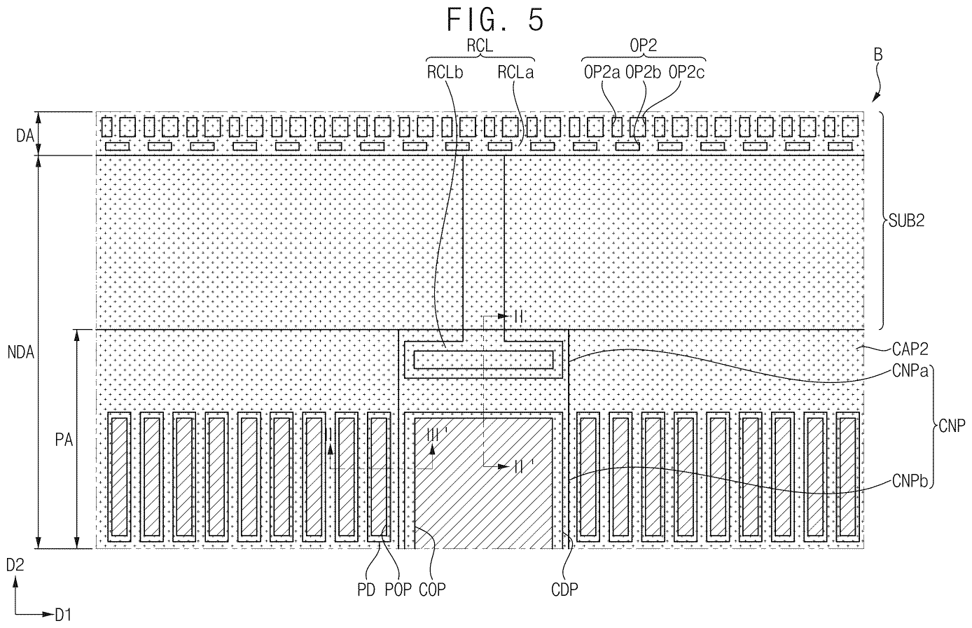

The connection portion RCLb of the reflective conductive layer RCL may have a shape extending from the mesh portion RCLa, which is arranged in the display area DA, to the pad area PA. The mesh portion RCLa and the connection portion RCLb of the reflective conductive layer RCL may be integrally formed. A detailed description of the connection portion RCLb will be provided later with reference to FIG. 5.

FIG. 5 is an enlarged plan view of an embodiment of the area B of FIG. 4.

Referring to FIG. 5, the reflective conductive layer RCL may include the mesh portion RCLa arranged in the display area DA and the connection portion RCLb extending from the mesh portion RCLa to the pad area PA. In one or more embodiments, a plurality of connection portions RCLb may be arranged along the first direction D1 (see FIG. 4).

In one or more embodiments, in a plan view, the connection portion RCLb may extend to the pad area PA beyond the second base substrate SUB2. This is to facilitate connection between the reflective conductive layer RCL and a conductive pattern CDP by using a connection pattern CNP.

The connection portion RCLb of the reflective conductive layer RCL, pads PD, the conductive patterns CDP, and the connection pattern CNP may be arranged in the pad area PA. In one or more embodiments, the pads PD may be arranged spaced and/or apart (e.g., spaced apart or separated) from each other in the first direction D1. However, the embodiments of present disclosure are not limited thereto, and the pads PD may be repeatedly arranged spaced and/or apart (e.g., spaced apart or separated) from each other in the first direction D1 and the second direction D2, in a plan view.

The conductive pattern CDP may be arranged in the pad area PA. In one or more embodiments, the conductive pattern CDP may be arranged spaced and/or apart (e.g., spaced apart or separated) from the connection portion RCLb, in a plan view. For example, the conductive pattern CDP may be spaced and/or apart (e.g., spaced apart or separated) from the connection portion RCLb in a direction opposite to the second direction D2 (e.g., in a direction opposite the direction pointed by the second direction D2), in a plan view. The conductive pattern CDP may be arranged between the pads PD. In one or more embodiments, in the pad area PA, a plurality of conductive patterns CDP may be arranged between the pads PD which are repeatedly arranged along the first direction D1, spaced and/or apart (e.g., spaced apart or separated) from the pads PD and the connection portion RCLb. In one or more embodiments, the conductive pattern CDP may be a pad which receives a voltage and/or control signal output from the integrated circuit IC.

The connection pattern CNP may be arranged on the connection portion RCLb and the conductive pattern CDP. For example, the connection pattern CNP may overlap with the connection portion RCLb and the conductive pattern CDP, in a plan view. In one or more embodiments, the connection pattern CNP may include a first portion CNPa which overlaps the connection portion RCLb in a plan view, and a second portion CNPb which overlaps the conductive pattern CDP in a plan view. In one or more embodiments, a constant voltage may be applied to the conductive pattern CDP. For example, the conductive pattern CDP may be applied with the common voltage which is applied to the common electrode CE. In other words, the conductive pattern CDP is configured to receive the common voltage which is applied to the common electrode CE. In one or more other embodiment, one or more suitable voltages, such as an initialization voltage, a reference voltage, and/or the like may be applied to the conductive pattern CDP.

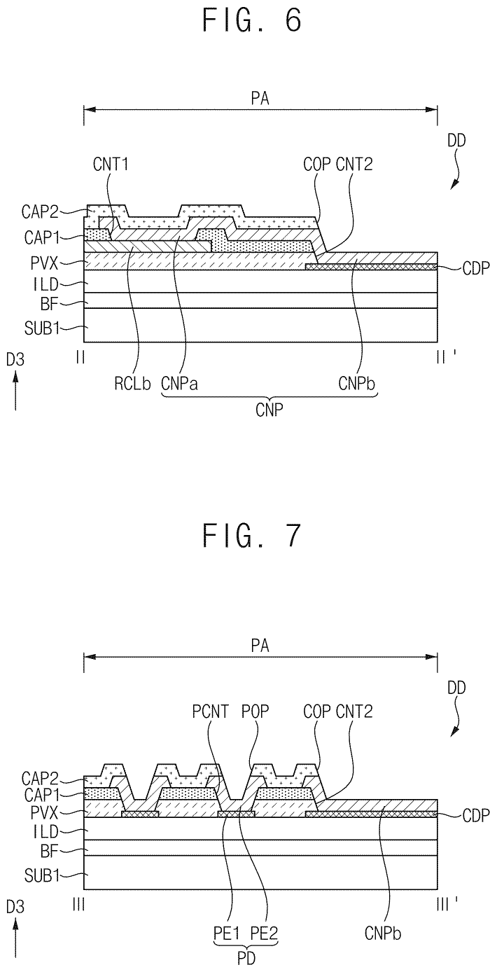

FIG. 6 is a cross-sectional view taken along the line II-II′ of FIG. 5 according to one or more embodiments of the present disclosure.

Referring to FIG. 3 and FIG. 6, the buffer layer BF and the interlayer insulating layer ILD may be sequentially arranged in the pad area PA in the third direction D3 on the first base substrate SUB1. The conductive pattern CDP may be arranged on the interlayer insulating layer ILD. In one or more embodiments, the conductive pattern CDP may include the same material as the connection electrodes SD. For example, the conductive pattern CDP may be formed concurrently (e.g., simultaneously) through the same process as the first connection electrode SD1 and the second connection electrode SD2.

The passivation layer PVX may be arranged in the pad area PA on the interlayer insulating layer ILD and the conductive pattern CDP. The connection portion RCLb of the reflective conductive layer RCL may be arranged in the pad area PA on the passivation layer PVX. The first capping layer CAP1 may be arranged in the pad area PA on the passivation layer PVX and the connection portion RCLb, for example, covering an edge of the connection portion RCLb. The connection pattern CNP may be arranged on the first capping layer CAP1, the connection portion RCLb of the reflective conductive layer RCL, the passivation layer PVX, and the conductive pattern CDP. The connection pattern CNP may include a conductive material.

In one or more embodiments, the first portion CNPa of the connection pattern CNP may be electrically connected to the connection portion RCLb of the reflective conductive layer RCL through a first contact hole CNT1 penetrating the first capping layer CAP1, and the second portion CNPb of the connection pattern CNP may be electrically connected to the conductive pattern CDP through a second contact hole CNT2 penetrating the first capping layer CAP1 and the passivation layer PVX. As a result, the reflective conductive layer RCL may be electrically connected to the conductive pattern CDP, to which a constant voltage is applied, through the connection pattern CNP. Accordingly, it may prevent or reduce electrostatic discharge defects or signal coupling problems caused by the reflective conductive layer RCL being left floating without being connected to another constant-voltage line. As a result, the reliability of the display device DD may be improved.

Referring to FIG. 5 and FIG. 6, the second capping layer CAP2 may be arranged in the pad area PA on the first capping layer CAP1 and the connection pattern CNP. The second capping layer CAP2 may cover the entire first portion CNPa of the connection pattern CNP.

In one or more embodiments, in case that the conductive pattern CDP is a pad which receives a voltage and/or control signal output from the integrated circuit IC, a connection pattern opening COP which exposes an upper surface of the second portion CNPb of the connection pattern CNP may be defined in the second capping layer CAP2. For example, the second portion CNPb of the connection pattern CNP exposed through the connection pattern opening COP may be electrically connected to a lead of the integrated circuit IC through an anisotropic conductive film ACF and/or the like. Accordingly, the conductive pattern CDP may receive the voltage and/or control signal from the integrated circuit IC through the connection pattern CNP.

FIG. 7 is a cross-sectional view taken along the line III-III′ of FIG. 5 according to one or more embodiments of the present disclosure.

Referring to FIG. 3 and FIG. 7, the buffer layer BF and the interlayer insulating layer ILD may be sequentially arranged in the pad area PA in the third direction D3 on the first base substrate SUB1. The pads PD may be arranged on the interlayer insulating layer ILD. Each of the pads PD may include a first pad electrode PE1 and a second pad electrode PE2.

The first pad electrode PE1 and the conductive pattern CDP may be arranged in the pad area PA on the interlayer insulating layer ILD. In one or more embodiments, the first pad electrode PE1 may include a same material as the conductive pattern CDP and the connection electrodes SD. For example, the first pad electrode PE1 may be formed concurrently (e.g., simultaneously) through the same process as the conductive pattern CDP, the first connection electrode SD1, and the second connection electrode SD2. The first pad electrode PE1, the conductive pattern CDP, the first connection electrode SD1, and the second connection electrode SD2 may be spaced and/or apart (e.g., spaced apart or separated) from each other and may be electrically insulated from each other.

The passivation layer PVX may be arranged in the pad area PA on the interlayer insulating layer ILD, the first pad electrode PE1, and the conductive pattern CDP, for example, covering edges of the first pad electrode PE1 and the conductive pattern CDP. The first capping layer CAP1 may be arranged in the pad area PA on the passivation layer PVX.

The second pad electrode PE2 and the second portion CNPb of the connection pattern CNP may be arranged in the pad area PA on the first capping layer CAP1. In one or more embodiments, the second pad electrode PE2 may include a same material as the connection pattern CNP. For example, the second pad electrode PE2 may be formed concurrently (e.g., simultaneously) through the same process as the connection pattern CNP. The second pad electrode PE2 and the connection pattern CNP may be spaced and/or apart (e.g., spaced apart or separated) from each other and may be electrically insulated from each other.

In one or more embodiments, the second pad electrode PE2 may be electrically connected to the first pad electrode PE1 through a pad contact hole PCNT penetrating the first capping layer CAP1 and the passivation layer PVX. The second pad electrode PE2 may include a conductive material. In addition, as mentioned above, the second portion CNPb of the connection pattern CNP may be electrically connected to the conductive pattern CDP through the second contact hole CNT2 penetrating the first capping layer CAP1 and the passivation layer PVX.

Referring to FIG. 5 and FIG. 7, the second capping layer CAP2 may be arranged in the pad area PA on the first capping layer CAP1, the second pad electrode PE2, and the second portion CNPb of the connection pattern CNP. In one or more embodiments, a pad opening POP exposing an upper surface of the second pad electrode PE2 may be defined in the second capping layer CAP2. For example, the second pad electrode PE2 exposed by the pad opening POP may be electrically connected to the lead of the integrated circuit IC through an anisotropic conductive film and/or the like. Accordingly, each of the pads PD may receive a voltage and/or control signal from the integrated circuit IC. The pads PD may be to transmit the voltage and/or control signal received from the integrated circuit IC to pixels in the display area DA or driving units in the non-display area NDA.

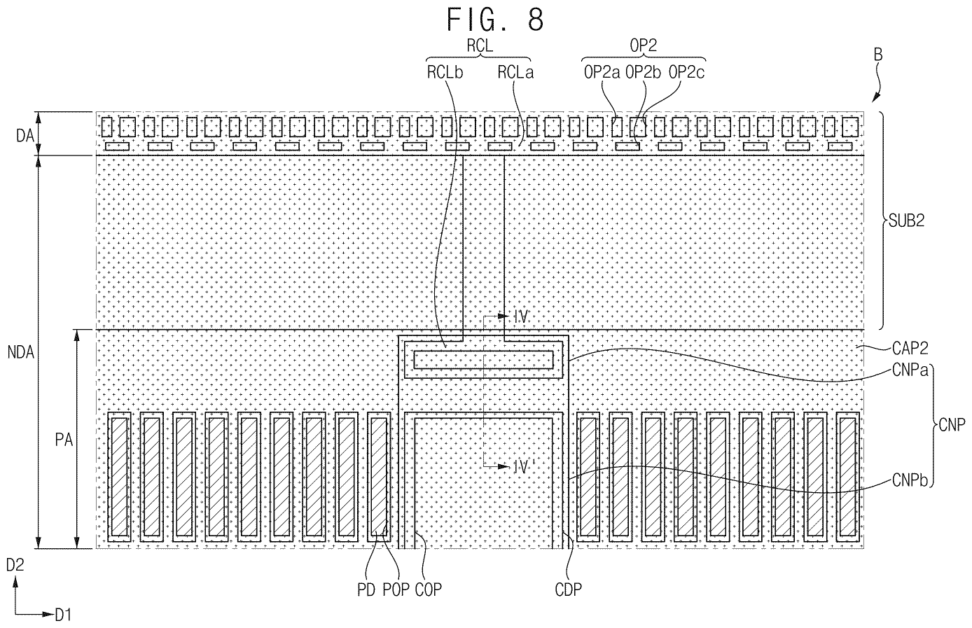

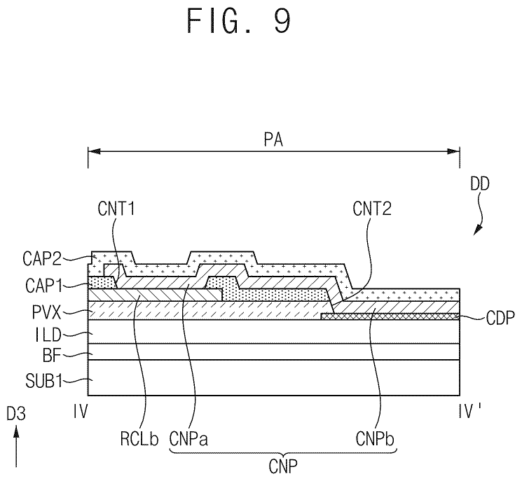

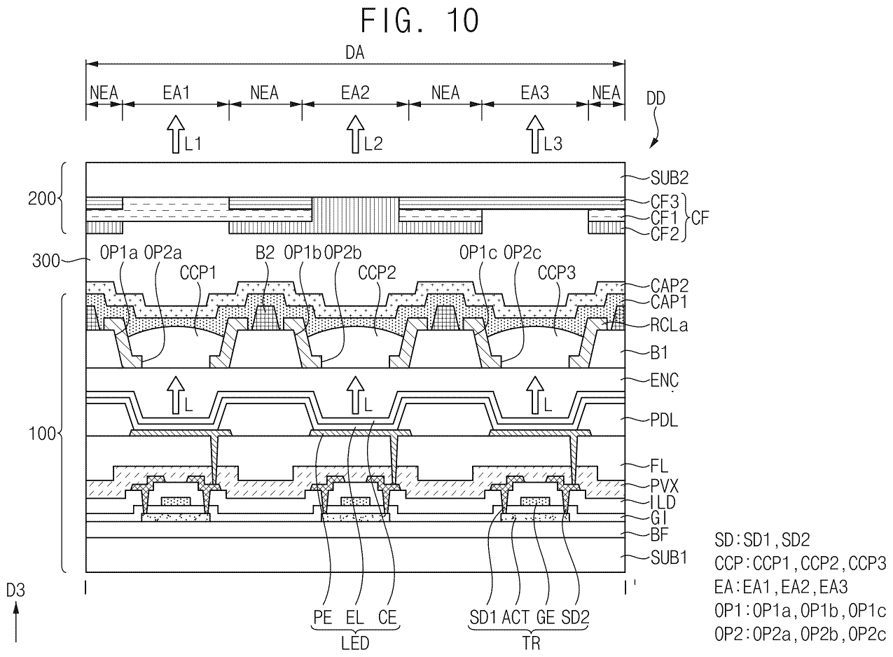

FIG. 8 is an enlarged plan view of another embodiment of area B of FIG. 4. FIG. 9 is a cross-sectional view taken along the line IV-IV′ of FIG. 8 according to one or more embodiments of the present disclosure. Hereinafter, redundant descriptions with the portions explained with reference to FIGS. 5 to 7 will not be provided or simplified.

Referring to FIG. 8 and FIG. 9, in one or more embodiments, the conductive pattern CDP may be a transmission line for transmitting a voltage and/or a control signal in the lower substrate 100. For example, the conductive pattern CDP may be a power transmission line for transmitting the common voltage to the common electrode CE of FIG. 3. In these embodiments, the second capping layer CAP2 may cover the entire second portion CNPb of the connection pattern CNP. For example, the second capping layer CAP2 may cover the entire connection pattern CNP. The second capping layer CAP2 may cover both (e.g., simultaneously) the first portion CNPa and the second portion CNPb of the connection pattern CNP.

FIG. 10 is a cross-sectional view of another embodiment taken along the line I-I′ of FIG. 2. Hereinafter, redundant descriptions with the portions explained with reference to FIG. 3 will not be provided or simplified.

Referring to FIG. 10, in one or more embodiments, the mesh portion RCLa of the reflective conductive layer RCL may cover a periphery of the first bank B1, and may expose a central portion of the first bank B1. The second bank B2 may be directly arranged on the central portion of the first bank B1, and may be spaced and/or apart (e.g., spaced apart or separated) from the mesh portion RCLa of the reflective conductive layer RCL. Accordingly, the occurrence of electrostatic discharge defects during the process may be prevented or reduced.

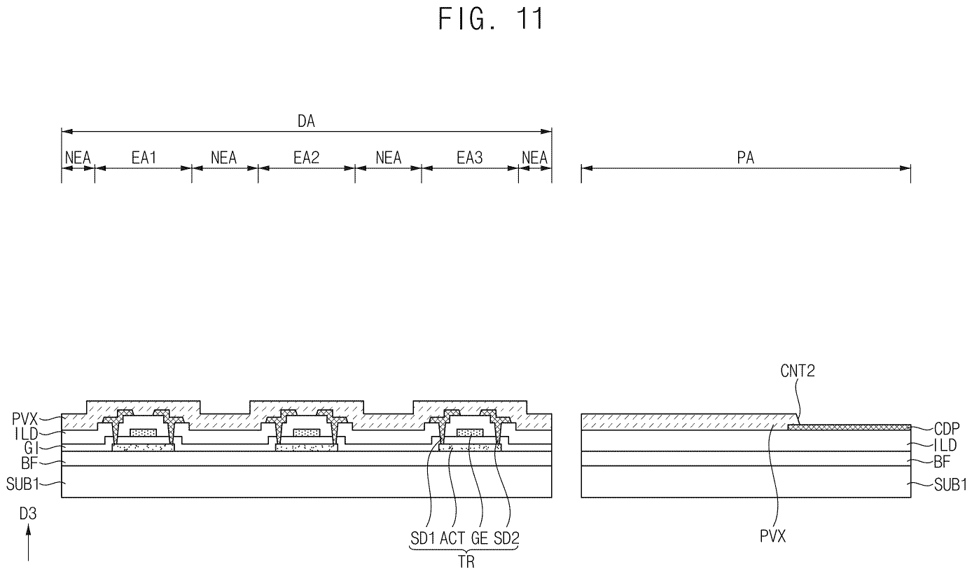

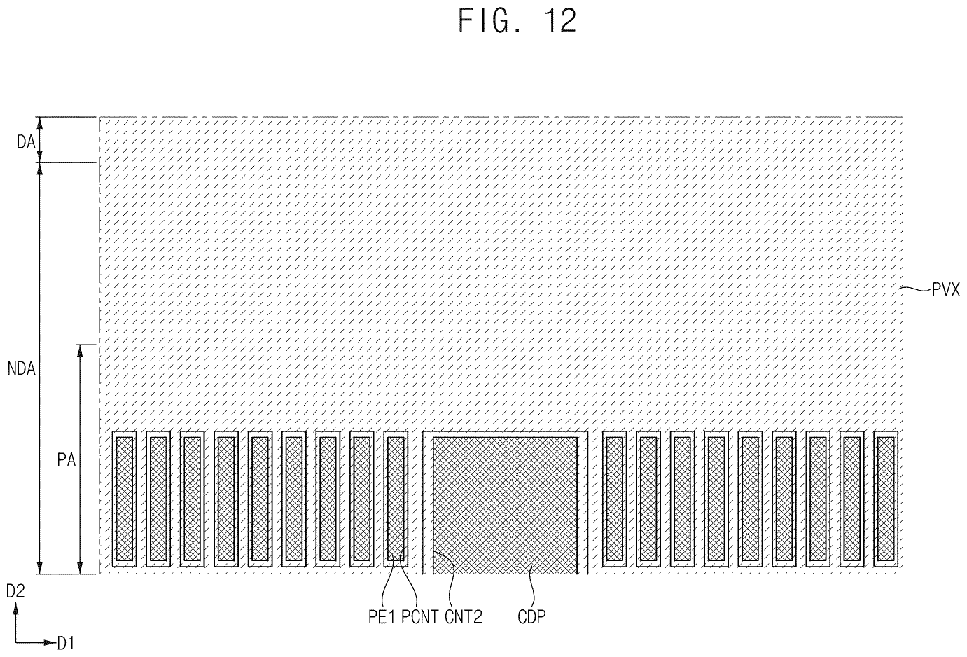

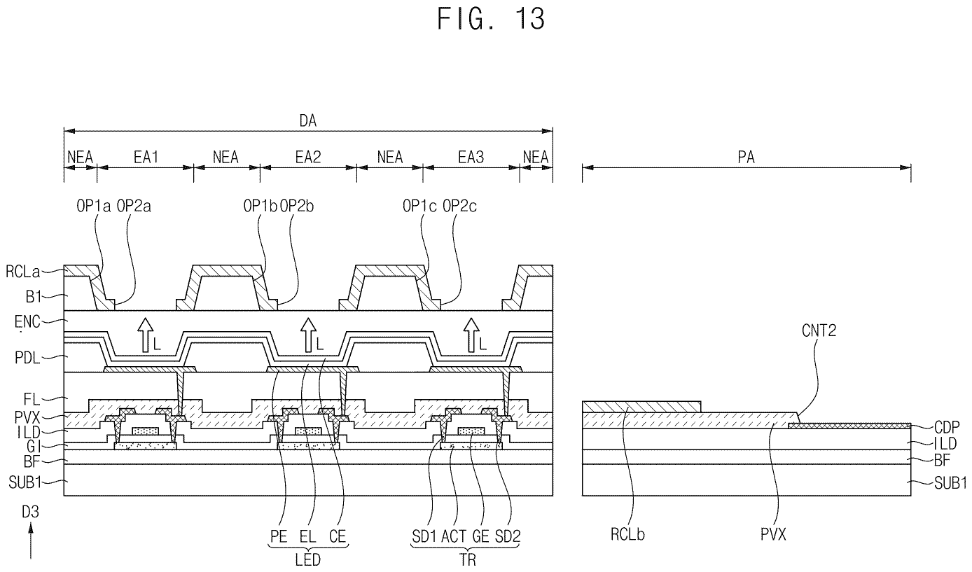

FIGS. 11 to 20 are views of a method of manufacturing a display device according to one or more embodiments of the present disclosure. FIGS. 11, 13, 15, 17, and 19 are cross-sectional views for explaining a method of manufacturing a display device according to one or more embodiments of the present disclosure. In each of FIGS. 11, 13, 15, 17, and 19, the cross-sectional view on the left may correspond to FIG. 3 (e.g., a portion of the display area DA), and the cross-sectional view on the right may correspond to FIG. 6 (e.g., a portion of the pad area PA). FIGS. 12, 14, 16, 18, and 20 are plan views of a method for manufacturing a display device according to one or more embodiments of the present disclosure. Each of FIGS. 12, 14, 16, 18, and 20 may correspond to FIG. 5.

Referring to FIG. 11 and FIG. 12, the buffer layer BF may be formed on the first base substrate SUB1. The active pattern ACT may be formed in the display area DA on the buffer layer BF. The gate insulating layer GI which entirely covers the active pattern ACT may be formed in the display area DA on the buffer layer BF. For example, the gate insulating layer GI may be formed using an inorganic insulating material.

The gate electrode GE may be formed in the display area DA on the gate insulating layer GI. The gate electrode GE may overlap the channel region of the active pattern ACT. For example, the gate electrode GE may be formed using a conductive material.

The interlayer insulating layer ILD may be formed on the gate insulating layer GI in the display area DA and on the buffer layer BF in the pad area PA. The interlayer insulating layer ILD may be formed to cover the entire gate electrode GE. For example, the interlayer insulating layer ILD may be formed using an inorganic insulating material.

The first connection electrode SD1 and the second electrode SD2 may be formed in the display area DA on the interlayer insulating layer ILD. The first connection electrode SD1 may be connected to the source region of the active pattern ACT through a contact hole penetrating the interlayer insulating layer ILD and the gate insulating layer GI. The second connection electrode SD2 may be connected to the drain region of the active pattern ACT through a contact hole penetrating the interlayer insulating layer ILD and the gate insulating layer GI. For example, the first connection electrode SD1 and the second connection electrode SD2 may be formed using a conductive material. Accordingly, the transistor TR including the active pattern ACT, the first connection electrode SD1, the second connection electrode SD2, and the gate electrode GE may be formed in the display area DA.

The conductive pattern CDP and the first pad electrode PE1 of FIG. 7 may be formed in the pad area PA on the interlayer insulating layer ILD. In one or more embodiments, the conductive pattern CDP and the first pad electrode PE1 may be formed concurrently (e.g., simultaneously) through the same process as the first connection electrode SD1 and the second connection electrode SD2. For example, a first conductive layer may be formed entirely in the display area DA and the pad area PA on the interlayer insulating layer ILD, and the first conductive layer may be patterned to concurrently (e.g., simultaneously) form the first connection electrode SD1, the second connection electrode SD2, the conductive pattern CDP, and the first pad electrode PE1 which are spaced and/or apart (e.g., spaced apart or separated) from each other.

The passivation layer PVX may be formed in the display area DA and the pad area PA on the interlayer insulating layer ILD. In one or more embodiments, in the pad area PA, the second contact hole CNT2 exposing the upper surface of the conductive pattern CDP may be formed by partially removing the passivation layer PVX overlapping the conductive pattern CDP. At the same time, the pad contact hole PCNT exposing the upper surface of the first pad electrode PE1 may be formed by partially removing the passivation layer PVX overlapping the first pad electrode PE1 (see FIG. 7). In one or more embodiments, the second contact hole CNT2 may be formed concurrently (e.g., simultaneously) with the pad contact hole PCNT through the same process. For example, the passivation layer PVX may be formed using an inorganic insulating material.

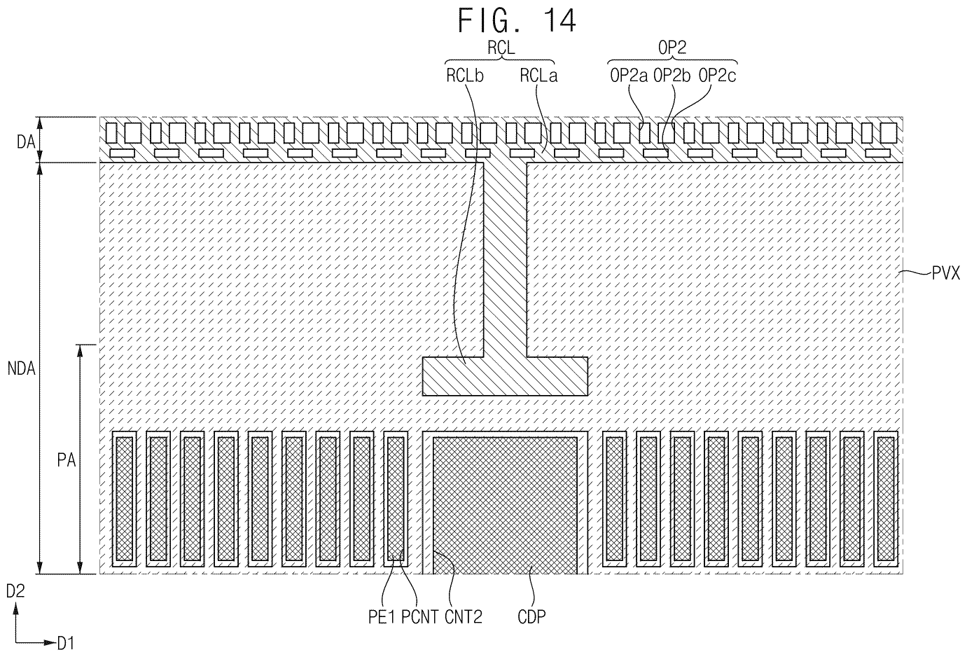

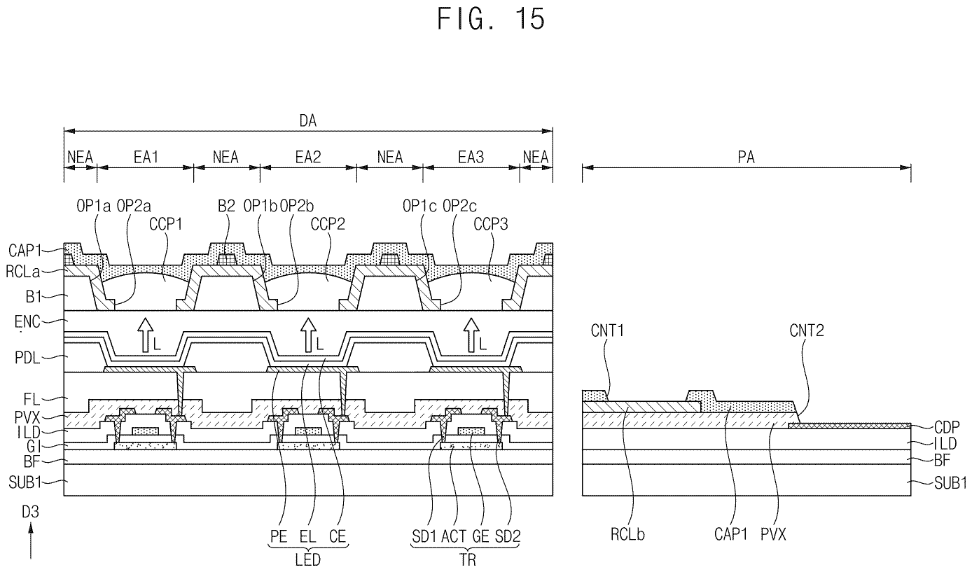

Referring to FIG. 13 and FIG. 14, the planarization layer FL may be formed in the display area DA on the passivation layer PVX. For example, the planarization layer FL may be formed using an organic material.

The pixel electrode PE may be formed in the display area DA on the planarization layer FL. In one or more embodiments, the pixel electrode PE may be connected to the second connection electrode SD2 through the contact hole penetrating the planarization layer FL and the passivation layer PVX. For example, the pixel electrode PE may be formed using a conductive material.

The pixel defining layer PDL may be formed in the display area DA on the planarization layer FL. The pixel defining layer PDL may cover the edge of the pixel electrode PE. For example, the pixel defining layer PDL may be formed using an organic material containing a light-blocking material.

The light-emitting layer EL may be formed in the display area DA on the pixel defining layer PDL. The light-emitting layer EL may be formed using an organic material which emits light of a preset color.

The common electrode CE may be formed in the display area DA on the pixel defining layer PDL and the light-emitting layer EL. For example, the common electrode CE may be formed using a conductive material.

The encapsulation layer ENC may be formed in the display area DA on the common electrode CE. The encapsulation layer ENC may be formed to include at least one inorganic layer and at least one organic layer.

The first bank B1 may be formed in the display area DA on the encapsulation layer ENC. The first bank B1 may be formed in the non-emission area NEA on the encapsulation layer ENC. The first bank B1 may form openings OP1 respectively corresponding to the emission areas EA. In one or more embodiments, the first bank B1 may form the first to third openings OP1a, OP1b, and OP1c. Each of the first to third openings OP1a, OP1b, and OP1c may be formed in the area corresponding to the first to third emission areas EA1, EA2, and EA3, respectively.

The reflective conductive layer RCL may be formed on (e.g., directly on) the encapsulation layer ENC, the first bank B1, and the passivation layer PVX. The reflective conductive layer RCL may include the mesh portion RCLa arranged in the display area DA and the connection portion RCLb extending from the mesh portion RCLa to the pad area PA. The mesh portion RCLa and the connection portion RCLb of the reflective conductive layer RCL may be integrally formed.

In one or more embodiments, the mesh portion RCLa may be formed to entirely cover the first bank B1 in the display area DA. For example, the mesh portion RCLa may be formed in the non-emission area NEA on the encapsulation layer ENC. In one or more embodiments, the mesh portion RCLa of the reflective conductive layer RCL may form the first to third reflection openings OP2a, OP2b, and OP2c. The first to third reflection openings OP2a, OP2b, and OP2c may be formed in the area corresponding to the first to third emission areas EA1, EA2, and EA3, respectively. The sizes of the first to third reflection openings OP2a, OP2b, and OP2c may be formed in one or more suitable ways as needed.

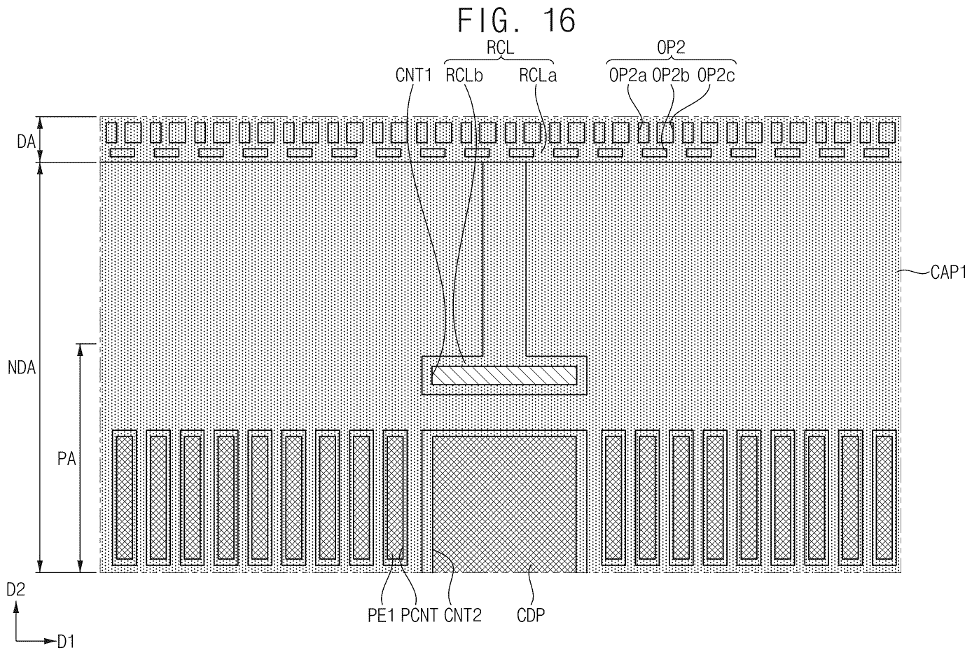

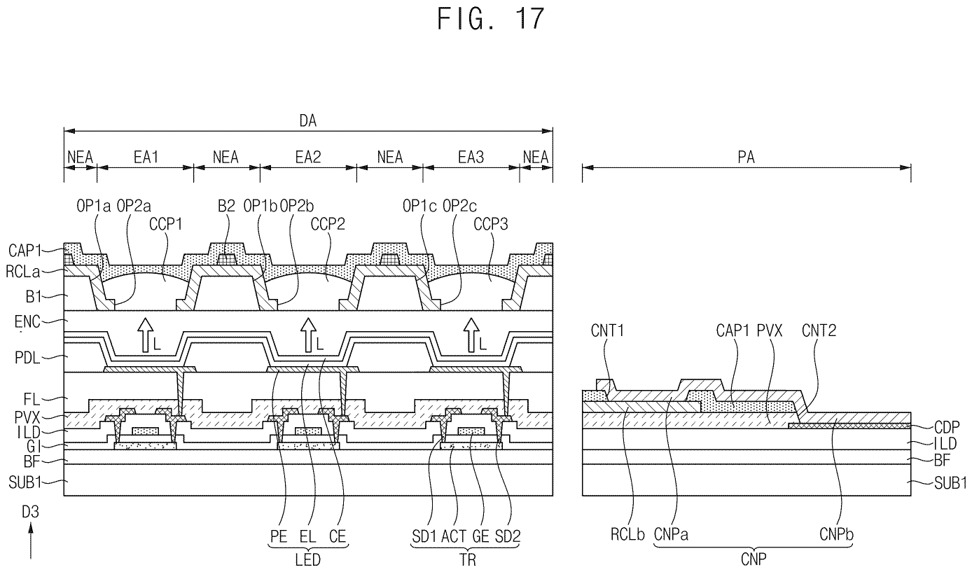

Referring to FIG. 15 and FIG. 16, the second bank B2 may be formed in the display area DA on the first bank B1. For example, the second bank B2 may be formed directly on the mesh portion RCLa which covers the entire first bank B1. For example, the second bank B2 may be formed using a liquid-repellent material.

The color conversion patterns CCP may be formed in the display area DA on the encapsulation layer ENC. The color conversion patterns CCP may be formed surrounded by the first bank B1. The first color conversion pattern CCP1, the second color conversion pattern CCP2, and the third color conversion pattern CCP may be formed by overlapping the first to third emission areas EA1, EA2, and EA3, respectively. For example, the color conversion patterns CCP may be formed using color conversion particles.

The first capping layer CAP1 may be formed in the display area DA on the reflective conductive layer RCL, the color conversion patterns CCP, and the second bank B2, and in the pad area PA on the reflective conductive layer RCL and on the passivation layer PVX. For example, the first capping layer CAP1 may be formed using an inorganic material.

In one or more embodiments, in the display area DA, the first capping layer CAP1 may entirely cover the mesh portion RCLa, the color conversion patterns CCP, and the second bank B2. In the pad area PA, the first contact hole CNT1 exposing an upper surface of the connection portion RCLb of the reflective conductive layer RCL may be formed by partially removing a portion of the first capping layer CAP1 overlapping the connection portion RCLb of the reflective conductive layer RCL. At the same time, the second contact hole CNT2 exposing the upper surface of the conductive pattern CDP may be formed by partially removing a portion of the first capping layer CAP1 and a portion of the passivation layer PVX overlapping the conductive pattern CDP, and the pad contact hole PCNT exposing the upper surface of the first pad electrode PE1 may be formed by partially removing a portion of the first capping layer CAP1 and a portion of the passivation layer PVX overlapping the first pad electrode PE1 (see FIG. 7). In one or more embodiments, the first contact hole CNT1 may be formed concurrently (e.g., simultaneously) with the second contact hole CNT2 and the pad contact hole PCNT through the same process.

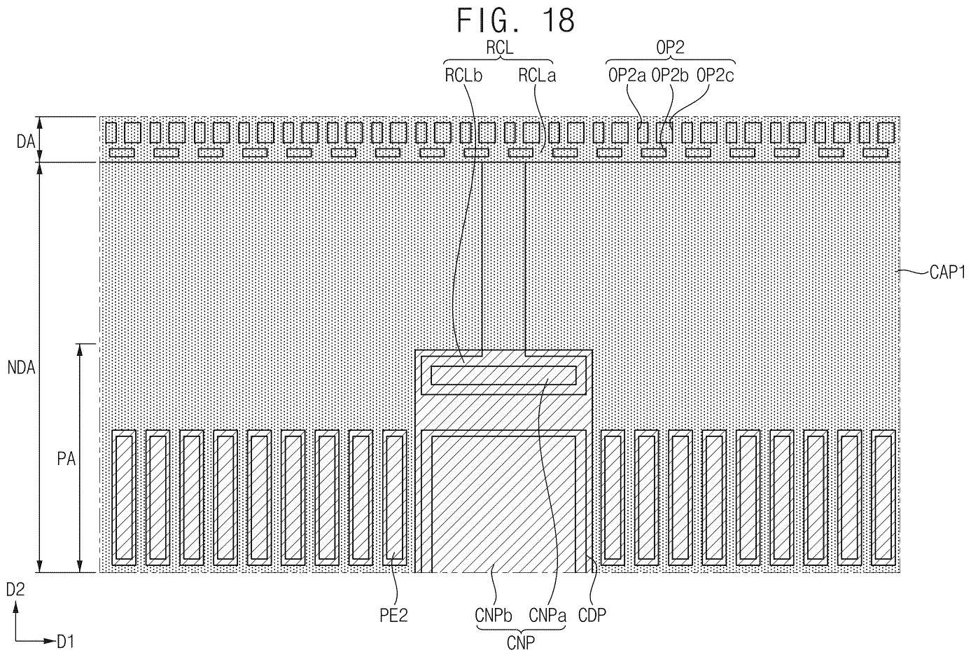

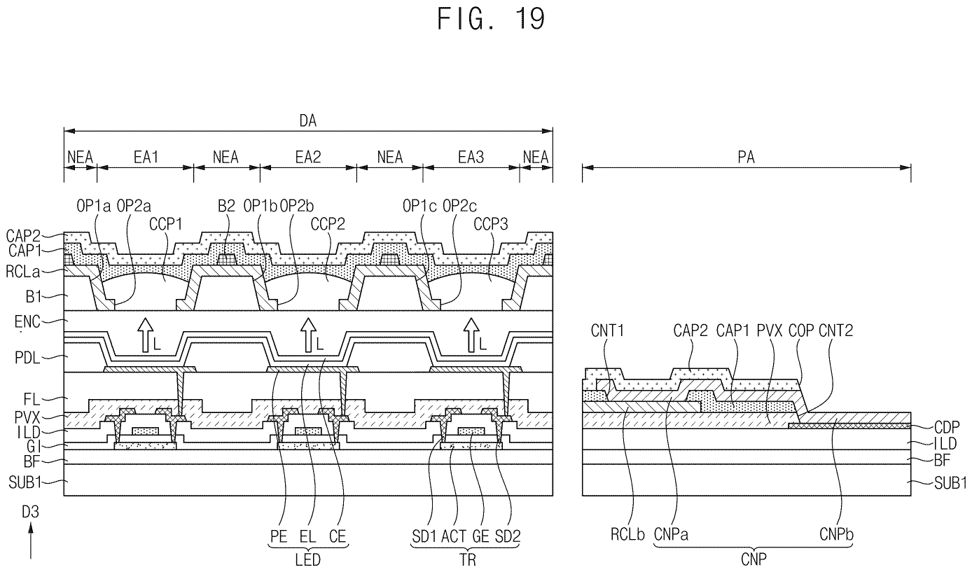

Referring to FIG. 17 and FIG. 18, the connection pattern CNP may be formed in the pad area PA on the conductive pattern CDP, the passivation layer PVX, the first capping layer CAP1, and the connection portion RCLb of the reflective conductive layer RCL. In one or more embodiments, the first portion CNPa of the connection pattern CNP may be formed on the connection portion RCLb of the reflective conductive layer RCL through the first contact hole CNT1 penetrating the first capping layer CAP1. At the same time, the second portion CNPb of the connection pattern CNP may be formed on the conductive pattern CDP through the second contact hole CNT2 penetrating the first capping layer CAP1 and the passivation layer PVX. The first portion CNPa and the second portion CNPb of the connection pattern CNP may be integrally formed. For example, the connection pattern may be formed using a conductive material.

As illustrated in FIG. 7, the second pad electrode PE2 may be formed on the first pad electrode PE1 through the pad contact hole PCNT penetrating the first capping layer CAP1 and the passivation layer PVX. In one or more embodiments, the second pad electrode PE2 may be formed concurrently (e.g., simultaneously) with the connection pattern CNP through the same process. For example, the second conductive layer may be formed entirely in the pad area PA on the first capping layer CAP1, and the second conductive layer may be patterned to concurrently (e.g., simultaneously) form the connection pattern CNP and the second pad electrode PE2 which are spaced and/or apart (e.g., spaced apart or separated) from each other.

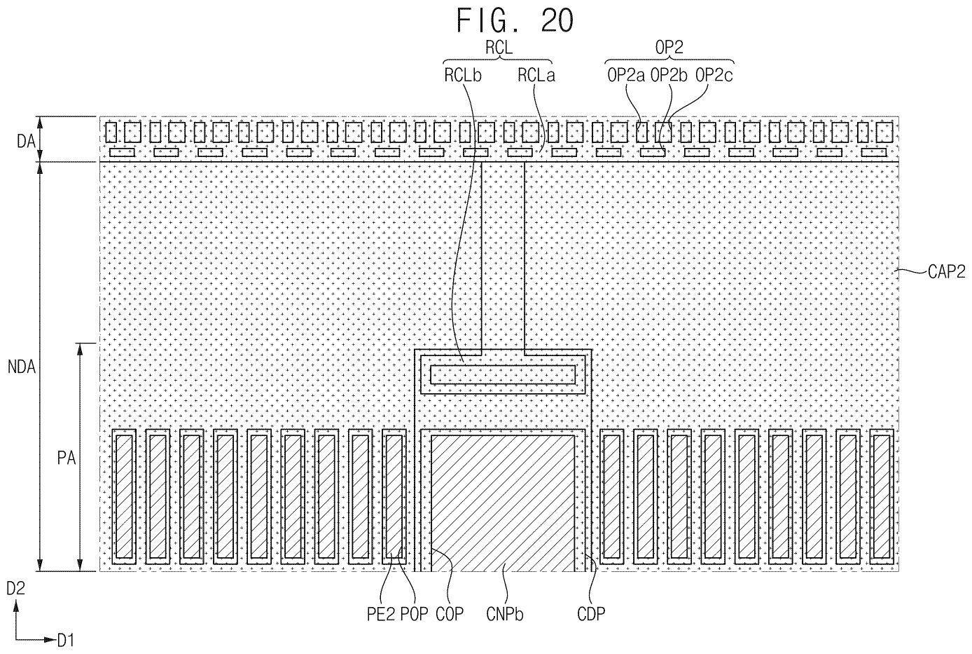

Referring to FIG. 19 and FIG. 20, the second capping layer CAP2 may be formed in the display area DA on the first capping layer CAP1, and in the pad area PA on the first capping layer CAP1 and the connection pattern CNP. For example, the second capping layer CAP2 may be formed using an inorganic material.

In one or more embodiments, in the display area DA, the second capping layer CAP2 may entirely cover the first capping layer CAP1. In the pad area PA, the second capping layer CAP2 may entirely cover the first portion CNPa of the connection pattern CNP. In one or more embodiments, in the pad area PA, the connection pattern opening COP exposing the upper surface of the second portion CNPb of the connection pattern CNP may be formed by partially removing a portion of the second capping layer CAP2 overlapping the second portion CNPb of the connection pattern CNP. At the same time, the pad opening POP exposing the upper surface of the second pad electrode PE2 may be formed by partially removing a portion of the second capping layer CAP2 overlapping the second pad electrode PE2 (see FIG. 7). In one or more embodiments, the connection pattern opening COP and the pad opening POP may be formed concurrently (e.g., simultaneously) through the same process.

The display device DD according to one or more embodiments of the present disclosure may be applied to one or more suitable electronic devices. An electronic device according to one or more embodiments may include the display device DD described above, and may further include a module or a device having additional functions in addition to the display device DD.

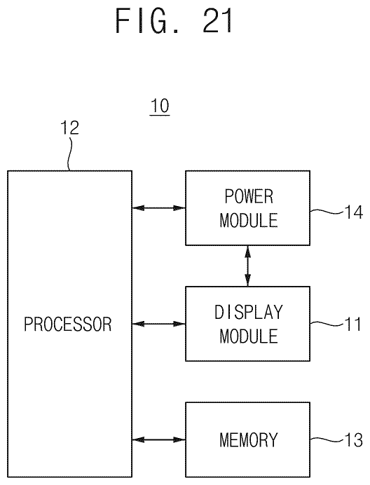

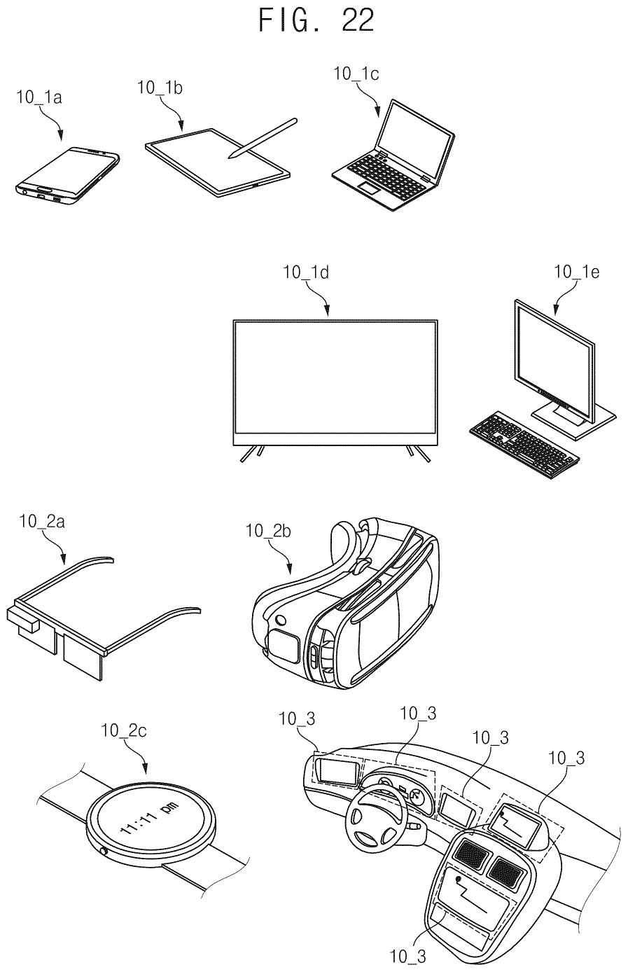

FIG. 21 is a block diagram of an electronic device according to one or more embodiments of the present disclosure.

Referring to FIG. 21, an electronic device 10 according to one or more embodiments may include a display module 11, a processor 12, a memory 13, and a power module 14.

The processor 12 may control the display device DD including the display module 11. The processor 12 may include at least one of a central processing unit (CPU), an application processor (AP), a graphic processing unit (GPU), a communication processor (CP), an image signal processor (ISP), or a controller.

The memory 13 may store date information necessary for operations of the processor 12 and/or the display module 11. When the processor 12 executes an application stored in the memory 13, an image data signal and/or an input control signal may be transmitted to the display module 11, and the display module 11 may processes the received signal and output image information through a display screen.

The power module 14 may include a power supply module, such as a power adapter or a battery device, and a power conversion module that converts the power supplied by the power supply module to generate power desired or required for operations of the electronic device 10.

At least one selected from among the components of the electronic device 10 described above may be included in the display device (e.g., the display device DD of FIG. 1) according to the above-described embodiments. Additionally, some of the individual modules functionally included in one module may be included in the display device DD, and other portions may be provided separately from the display device DD. For example, the display device DD may include the display module 11, and the processor 12, the memory 13, and the power module 14 may be provided in the form of other devices within the electronic device 10 other than the display device DD.

FIG. 22 illustrates schematic diagrams of electronic device according to one or more embodiments of the present disclosure.

Referring to FIG. 22, one or more suitable electronic devices 10 to which a display device according to one or more embodiments (e.g., the display device DD of FIG. 1) is applied may include not only image display electronic devices, such as a smartphone 10_1a, a tablet PC 10_1b, a laptop 10_1c, a TV 10_1d, and a desktop monitor 10_1e, but also wearable electronic devices including display modules, such as smart glasses 10_2a, a head-mounted display 10_2b, and a smart watch 10_2c, and automotive electronic devices 10_3 including display modules, such as a dashboard of a car, a center fascia, a center information display (CID) located on the dashboard, a room mirror display of the car, and/or the like.

Embodiments of the present disclosure may be applied to display devices and electronic devices including the same. For example, embodiments of the present disclosure may be applied to high-resolution smartphones, mobile phones, smart pads, smart watches, tablet PCs, vehicle navigation systems, television, computer monitors, laptops, and/or the like.

In the disclosure, if (e.g., when) it is mentioned that a component (or an area, a layer, a part, and/or the like) is “on”, “located on”, “connected to”, or “coupled to” another component, it refers to that the former component may be directly on, located on, connected to, or coupled to the latter component or a third component may be arranged between the components. In contrast, if (e.g., when) an element is referred to as being “directly on” or “directly located on” another element, there are no intervening element present therebetween.

In the disclosure, in the drawings, thicknesses, ratios, dimensions of the components may be exaggerated for an effective description of the technical contents. The term “and/or” or “or” may include one or more combinations that may be defined by the associated components.

Furthermore, in describing the one or more suitable components, the terms, such as “first” and “second” may be used, but embodiments of the present disclosure are not limited by the terms. The terms are simply for distinguishing the components. For example, a first component may be named a second component, and similarly a second component also may be named a first component while not departing from the scope of the present disclosure. As used herein, a singular expression includes a plural expression unless an exemption is explicitly described in the context. For example, the singular forms “a,” “an,” “one,” and “the” are intended to include the plural forms as well, unless the context clearly indicates otherwise. Further, the use of “may” when describing embodiments of the present disclosure refers to “one or more embodiments of the present disclosure.”

Spatially relative terms, such as “beneath,” “below,” “lower,” “under,” “above,” “upper,” and/or the like, may be used herein for descriptive purposes, and, thereby, to describe one element or feature's relationship to another element(s) or feature(s) as shown in the drawings. Spatially relative terms are intended to encompass different orientations of a device in use, operation, and/or manufacture in addition to the orientation depicted in the drawings. For example, if (e.g., when) the device in the drawings is turned upside down, elements described as “below” or “beneath” or “under” other elements or features would then be oriented “above” or “on” the other elements or features. Thus, in one or more embodiments, the example term “below” may encompass both (e.g., simultaneously) an orientation of above and below directions. Furthermore, the device may be otherwise oriented (e.g., rotated 90 degrees or at other orientations), and, as such, the spatially relative descriptors used herein interpreted accordingly.

When the terms, such as “comprise(s)/comprising” and/or “include(s)/including” and/or “has(have)/having”, are used in the disclosure, it should be understood that they specify presence of the stated features, numbers, steps, operations, components, parts, and/or one or more (e.g., any suitable) combinations thereof, but do not exclude presence or addition of one or more other features, numbers, steps, operations, components, parts, and/or one or more (e.g., any suitable) combinations thereof. Additionally, the terms “comprise(s)/comprising,” “include(s)/including,” “has(have)/having”, or other similar terms include or support the terms “consisting of” and “consisting essentially of,” indicating the presence of stated features, numbers, steps, operations, parts, and/or components, without or essentially without the presence of other features, numbers, steps, operations, parts, components, and/or groups thereof.

In the present disclosure, expressions such as “at least one of,” “one of,” and “selected from,” when preceding a list of elements, modify the entire list of elements and do not modify the individual elements of the list. For example, “at least one of a, b or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof.

In the context of the present application and unless otherwise defined, the terms “use,” “using,” and “used” may be considered synonymous with the terms “utilize,” “utilizing,” and “utilized,” respectively.

As utilized herein, the terms “substantially,” “about,” “approximately,” or similar terms are used as terms of approximation and not as terms of degree, and are intended to account for the inherent deviations in measured or calculated values that would be recognized by those of ordinary skill in the art. “About” or “approximately” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” or “approximately” may mean within one or more standard deviations, or within ±30%, ±20%, ±10%, or ±5% of the stated value. Also, it should be understood that, even if the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this disclosure, including the claims, to expressly recite any sub-range subsumed within the ranges expressly recited herein.

The light-emitting element, the display panel, the display module, the display device, the electronic devices/apparatus, the device-manufacturing apparatus, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

The foregoing is illustrative of example embodiments and is not to be construed as limiting thereof. Although a few embodiments have been described, those skilled in the art will readily appreciate that many modifications are possible in one or more embodiments without materially departing from the teachings and advantages of the present disclosure. Accordingly, all such modifications are intended to be included within the scope of the present disclosure as defined in the appended claims and equivalents thereof.

What is claimed is:

1. A display device, comprising:
a first base substrate comprising
a display area comprising emission areas and a non-emission area around the emission areas, and
a pad area outside the display area;
a plurality of transistors in the display area on the first base substrate;
a conductive pattern in the pad area on the first base substrate;
a passivation layer on the transistors and the conductive pattern;
a plurality of light-emitting elements respectively arranged in the emission areas on the passivation layer and respectively electrically connected to the transistors;
an encapsulation layer on the light-emitting elements;
a first bank in the non-emission area on the encapsulation layer and defining openings respectively corresponding to the emission areas;
a reflective conductive layer comprising
a mesh portion at least partially covering the first bank in the display area and
a connection portion extending from the mesh portion to the pad area;
a plurality of color conversion patterns respectively arranged in the openings of the first bank;
a first capping layer on the first bank, the reflective conductive layer, and the color conversion patterns; and
a connection pattern on the first capping layer and electrically connecting the connection portion of the reflective conductive layer and the conductive pattern.

2. The display device of claim 1, wherein the connection pattern comprises:
a first portion overlapping the connection portion of the reflective conductive layer in the pad area, in a plan view; and
a second portion overlapping the conductive pattern in the pad area, in a plan view.

3. The display device of claim 2, wherein the first portion of the connection pattern is connected to the connection portion of the reflective conductive layer through a first contact hole penetrating the first capping layer, and
wherein the second portion of the connection pattern is connected to the conductive pattern through a second contact hole penetrating the first capping layer and the passivation layer.

4. The display device of claim 2, further comprising:
a second capping layer on the first capping layer and the connection pattern.

5. The display device of claim 4, wherein the second capping layer covers the entire first portion of the connection pattern.

6. The display device of claim 5, wherein a connection pattern opening is defined in the second capping layer to expose an upper surface of the second portion of the connection pattern.

7. The display device of claim 5, wherein the second capping layer covers the entire second portion of the connection pattern.

8. The display device of claim 4, further comprising:
pads in the pad area and spaced from each other in a direction.

9. The display device of claim 8, wherein each of the pads comprises:
a first pad electrode under the passivation layer; and
a second pad electrode on the first capping layer and electrically connected to the first pad electrode.

10. The display device of claim 9, wherein the second pad electrode is connected to the first pad electrode through a pad contact hole penetrating the first capping layer and the passivation layer.

11. The display device of claim 9, wherein the second pad electrode and the connection pattern are in a same layer.

12. The display device of claim 9, wherein a pad opening is defined in the second capping layer to expose an upper surface of the second pad electrode.

13. The display device of claim 1, wherein a constant voltage is configured to be applied to the conductive pattern.

14. The display device of claim 1, further comprising:
a second base substrate opposite to the first base substrate;
a color filter layer under the second base substrate; and
a filling layer between the color filter layer and the first capping layer.

15. The display device of claim 14, wherein the connection portion of the reflective conductive layer extends beyond the second base substrate, in a plan view.

16. The display device of claim 1, further comprising:
a second bank on the first bank and comprising a liquid-repellent material.

17. The display device of claim 16, wherein the mesh portion of the reflective conductive layer covers the entire first bank, and
wherein the second bank is directly on the mesh portion of the reflective conductive layer.

18. The display device of claim 16, wherein the mesh portion of the reflective conductive layer covers a peripheral portion of the first bank and exposes a central portion of the first bank, and
wherein the second bank is directly on the central portion of the first bank and spaced from the mesh portion of the reflective conductive layer.

19. A method, comprising:
forming transistors in a display area on a first base substrate, the display area comprising emission areas and a non-emission area around the emission areas and a pad area outside the display area;
forming a conductive pattern in the pad area;
forming a passivation layer on the transistors and the conductive pattern;
forming light-emitting elements respectively electrically connected to the transistors in the emission areas on the passivation layer;
forming an encapsulation layer on the light-emitting elements;
forming a first bank in the non-emission area on the encapsulation layer, the first bank defining openings respectively corresponding to the emission areas;
forming a reflective conductive layer comprising a mesh portion at least partially covering the first bank in the display area and a connection portion extending from the mesh portion to the pad area;
forming color conversion patterns respectively in the openings of the first bank;
forming a first capping layer on the first bank, the reflective conductive layer, and the color conversion patterns; and
forming a connection pattern electrically connecting the connection portion of the reflective conductive layer and the conductive pattern on the first capping layer,
wherein the method is a method of manufacturing a display device.

20. An electronic device, comprising:
a display device comprising:
a first base substrate comprising a display area comprising emission areas and a non-emission area around the emission areas, and a pad area outside the display area;
a plurality of transistors in the display area on the first base substrate;
a conductive pattern in the pad area on the first base substrate;
a passivation layer on the transistors and the conductive pattern;
a plurality of light-emitting elements respectively arranged in the emission areas on the passivation layer and respectively electrically connected to the transistors;
an encapsulation layer on the light-emitting elements;
a first bank in the non-emission area on the encapsulation layer and defining openings respectively corresponding to the emission areas;
a reflective conductive layer comprising a mesh portion at least partially covering the first bank in the display area and a connection portion extending from the mesh portion to the pad area;
a plurality of color conversion patterns respectively in the openings of the first bank;
a first capping layer on the first bank, the reflective conductive layer. And the color conversion patterns; and
a connection pattern on the first capping layer and electrically connecting the connection portion of the reflective conductive layer and the conductive pattern; and
a processor configured to control the display device.
